(19) United States
(12) Patent Application Publication
(10) Pub. No.: US 2026/0281253 A1
(43) Pub. Date: Sep. 17, 2026

(54) PROCESSING HAPTIC INFORMATION

(71) Applicant: Tencent Technology (Shenzhen) Company Limited, Shenzhen (CN)

(72) Inventors: Ying HU, Shenzhen (CN); Xiaozhong XU, Shenzhen (CN)

(73) Assignee: Tencent Technology (Shenzhen) Company Limited, Shenzhen, GD (CN)

(21) Appl. No.: 19/672,226

(22) Filed: May 8, 2026

Related U.S. Application Data
(63) Continuation of application No. PCT/CN2024/109297, filed on Aug. 1, 2024.

(30) Foreign Application Priority Data
Dec. 11, 2023 (CN) 202311695315.8

(51) Int. Cl. H04M 19/04

(52) U.S. Cl. CPC H04M 19/047

(57) ABSTRACT

In a method for processing haptic information, a media file that includes a haptic experience dataset is obtained, and a bit stream corresponding to the haptic experience dataset is obtained from the media file, the bit stream including one or more data units, and each one of the one or more data units including one or more data packets and a syntax structure that includes (i) a data unit type indicator indicating a type of the data unit and (ii) a unit-level timestamp indicating an offset time of the data unit from a start time of the haptic experience dataset. In the method, the bit stream is decoded into a piece of text-based interchange format data indicating haptic information of the haptic experience dataset, and one or more haptic devices are driven based on the piece of text-based interchange format data.

### RELATED APPLICATIONS

The present application is a continuation of International Application No. PCT/CN2024/109297, filed on Aug. 1, 2024, which claims priority to Chinese Patent Application No. 202311695315.8, filed on Dec. 11, 2023, and entitled “METHOD AND APPARATUS FOR PROCESSING HAPTIC INFORMATION, ELECTRONIC DEVICE, AND STORAGE MEDIUM.” The entire disclosures of the prior applications are hereby incorporated by reference.

### FIELD OF THE TECHNOLOGY

Embodiments of this disclosure relate to the field of multimedia information processing technologies, including a method and apparatus for processing haptic information, an electronic device, and a storage medium.

### BACKGROUND OF THE DISCLOSURE

Presentation of content of immersive media is usually accompanied by use of various wearable devices or interactive devices. In addition to visual and audio presentation, presentation manners for the immersive media further include a haptic presentation manner. Haptic presentation may be implemented through a haptic presentation mechanism combining hardware and software. The haptic presentation manner provides an embedded physical feeling. A user may receive information of a system that the user is using through the body. For example, vibration is a type of haptic presentation, and a mobile phone vibrates to remind its user that an incoming call or information is received.

In a related technology, storage space occupied by haptic media content is relatively large, and bandwidth consumption is relatively large during transmission. In the related technology, a solution that can reduce occupied storage space and reduce bandwidth usage during transmission of the haptic media content is needed.

### SUMMARY

This disclosure provides a method and apparatus for processing haptic information, an electronic device, and a storage medium, and can reduce storage space occupied by haptic media content, and reduce bandwidth usage during transmission of the haptic media content.

According to a first aspect, an embodiment of this disclosure provides a method for processing haptic information. In the method, a media file that includes a haptic experience dataset is obtained. In the method, a bit stream corresponding to the haptic experience dataset is obtained by processing circuitry from the media file, the bit stream including one or more data units, and each one of the one or more data units including one or more data packets and a syntax structure that includes (i) a data unit type indicator indicating a type of the data unit and (ii) a unit-level timestamp indicating an offset time of the data unit from a start time of the haptic experience dataset. In the method, the bit stream is decoded by the processing circuitry into a piece of text-based interchange format data indicating haptic information of the haptic experience dataset. In the method, one or more haptic devices are driven based on the piece of text-based interchange format data.

According to a second aspect, an embodiment of this disclosure provides a method for processing haptic information. In the method, a piece of text-based interchange format data indicating haptic information is obtained. In the method, the piece of text-based interchange format data is encoded by processing circuitry into a bit stream corresponding to a haptic experience dataset incorporating the haptic information, the bit stream including one or more data units, and each one of the one or more data units including one or more data packets and a syntax structure that includes (i) a data unit type indicator indicating a type of the data unit and (ii) a unit-level timestamp indicating an offset time of the data unit from a start time of the haptic experience dataset. In the method, a media file encapsulating the haptic experience dataset is obtained by the processing circuitry. In the method, the media file is transmitted to a processing device that is configured to decode the media file into the piece of text-based interchange format data and drive one or more haptic devices based on the piece of text-based interchange format data.

According to a third aspect, an embodiment of this disclosure provides a haptic information processing device that includes processing circuitry configured to obtain a media file that includes a haptic experience dataset. The processing circuitry is configured to obtain, from the media file, a bit stream corresponding to the haptic experience dataset, the bit stream including one or more data units, and each one of the one or more data units including one or more data packets and a syntax structure that includes (i) a data unit type indicator indicating a type of the data unit and (ii) a unit-level timestamp indicating an offset time of the data unit from a start time of the haptic experience dataset. The processing circuitry is configured to decode the binary bit stream into a piece of text-based interchange format data indicating haptic information of the haptic experience dataset. The processing circuitry is configured to drive one or more haptic devices based on the piece of text-based interchange format data.

According to a third aspect, an embodiment of this disclosure provides a haptic information processing device that includes processing circuitry configured to obtain a piece of text-based interchange format data indicating haptic information. The processing circuitry is configured to encode the piece of text-based interchange format data into a bit stream corresponding to a haptic experience dataset incorporating the haptic information, the bit stream including one or more data units, and each one of the one or more data units including one or more data packets and a syntax structure that includes (i) a data unit type indicator indicating a type of the data unit and (ii) a unit-level timestamp indicating an offset time of the data unit from a start time of the haptic experience dataset. The processing circuitry is configured to transmit the media file to a processing device that is configured to decode the media file into the piece of text-based interchange format data and drive one or more haptic devices based on the piece of text-based interchange format data.

According to a fifth aspect, an embodiment of this disclosure provides a non-transitory computer-readable storage medium storing instructions, which when executed by a processor, cause the processor to perform a method for processing haptic information. In the method, a media file that includes a haptic experience dataset is obtained. In the method, a bit stream corresponding to the haptic experience dataset is obtained by processing circuitry from the media file, the bit stream including one or more data units, and each one of the one or more data units including one or more data packets and a syntax structure that includes (i) a data unit type indicator indicating a type of the data unit and (ii) a unit-level timestamp indicating an offset time of the data unit from a start time of the haptic experience dataset. In the method, the bit stream is decoded by the processing circuitry into a piece of text-based interchange format data indicating haptic information of the haptic experience dataset. In the method, one or more haptic devices are driven based on the piece of text-based interchange format data.

According to a fifth aspect, an embodiment of this disclosure provides a non-transitory computer-readable storage medium storing instructions, which when executed by a processor, cause the processor to perform a method for processing haptic information. In the method, a piece of text-based interchange format data indicating haptic information is obtained. In the method, the piece of text-based interchange format data is encoded by processing circuitry into a bit stream corresponding to a haptic experience dataset incorporating the haptic information, the bit stream including one or more data units, and each one of the one or more data units including one or more data packets and a syntax structure that includes (i) a data unit type indicator indicating a type of the data unit and (ii) a unit-level timestamp indicating an offset time of the data unit from a start time of the haptic experience dataset. In the method, a media file encapsulating the haptic experience dataset is obtained by the processing circuitry. In the method, the media file is transmitted to a processing device that is configured to decode the media file into the piece of text-based interchange format data and drive one or more haptic devices based on the piece of text-based interchange format data.

According to a seventh aspect, an embodiment of this disclosure provides a method for processing haptic information performed by a processor. The method includes: decapsulating a media file including target haptic information to obtain a binary bit stream corresponding to the target haptic information, the bit stream including: one or more data units regarding the target haptic information, and the data units including one or more data packets; and decoding the binary bit stream corresponding to the target haptic information to obtain an interchange format of the target haptic information, the interchange format of the target haptic information being configured for rendering and presenting the target haptic information.

According to an eighth aspect, an embodiment of this disclosure provides an apparatus for processing haptic information. The apparatus includes a decapsulation module and a decoding module. The decapsulation module is configured to decapsulate a media file including target haptic information to obtain a binary bit stream corresponding to the target haptic information. The bit stream includes one or more data units regarding the target haptic information, and the data units include one or more data packets. The decoding module is configured to decode the binary bit stream corresponding to the target haptic information to obtain an interchange format of the target haptic information. The interchange format of the target haptic information is configured for rendering and presenting the target haptic information.

According to a ninth aspect, an embodiment of this disclosure provides a method for processing haptic information performed by a processor. The method includes: encoding the interchange format of the target haptic information to obtain a binary bit stream corresponding to the target haptic information, the bit stream including: one or more data units regarding the target haptic information, and the data units including one or more data packets; and encapsulating the bit stream to obtain a media file including the haptic information.

According to a tenth aspect, an embodiment of this disclosure provides an apparatus for processing haptic information. The apparatus includes an encoding module and an encapsulation module. The encoding module is configured to encode the interchange format of the target haptic information to obtain the binary bit stream corresponding to the target haptic information. The bit stream includes one or more data units about the target haptic information, and the data units include one or more data packets. The encapsulation module is configured to encapsulate the bit stream to obtain the media file including the haptic information.

According to an eleventh aspect, an embodiment of this disclosure provides an electronic device including a processor and a memory. The memory is configured to store a computer program, and the processor is configured to invoke and run the computer program stored in the memory to perform the method for processing haptic information provided in the seventh aspect or the eighth aspect.

According to a twelfth aspect, an embodiment of this disclosure provides a chip, configured to implement the method in any implementation in the seventh aspect or various implementations thereof. In at least one aspect, the chip includes a processor configured to invoke and run the computer program from the memory, so that a device having the chip installed therein can perform the method for processing haptic information provided in the seventh aspect or the eighth aspect.

According to a thirteenth aspect, an embodiment of this disclosure provides a non-transitory computer-readable storage medium configured to store the computer program. The computer program causes a computer to execute the method for processing haptic information provided in the seventh aspect or the eighth aspect.

According to a fourteenth aspect, an embodiment of this disclosure provides a computer program product, which includes a computer program instruction. The computer program instruction causes the computer to perform the method for processing haptic information provided in the seventh aspect or the eighth aspect.

According to a fifteenth aspect, an embodiment of this disclosure provides a computer program. When being executed on the computer, the computer program causes the computer to perform the method for processing haptic information provided in the seventh aspect or the eighth aspect.

Based on the above, in one or more solutions provided in this disclosure, the interchange format of the target haptic information is encoded to obtain the binary bit stream corresponding to the target haptic information. Further, the binary bit stream may be encapsulated to obtain the media file including the haptic information. Embodiments of this disclosure provide a solution of encoding the interchange format of the haptic information into the binary bit stream. In at least one aspect, data is organized and divided in a form of data units and data packets in the binary bit stream, and a data unit includes one or more data packets. One or more solutions provided in embodiments of this disclosure can facilitate saving of storage space occupied by haptic media content, and can reduce bandwidth usage during transmission of the haptic media content.

### BRIEF DESCRIPTION OF THE DRAWINGS

To describe one or more technical solutions of this disclosure, the following briefly describes the accompanying drawings for describing one or more embodiments of this disclosure. The drawings in the following description show merely some embodiments of this disclosure, and a person of ordinary skill in the art may still derive other drawings from these drawings.

FIG. 1 is a schematic diagram of a haptic information representation and transmission system architecture in an audio video coding standard AVS (Audio Video Coding Standard);

FIG. 2 is a schematic diagram of an application scenario for processing haptic information according to an embodiment of this disclosure;

FIG. 3 is a schematic diagram of information interaction in a method for processing haptic information according to an embodiment of this disclosure;

FIG. 4 is a schematic diagram of a haptic information representation data structure in the audio video coding standard AVS;

FIG. 5 is a schematic flowchart of a method for processing haptic information according to an embodiment of this disclosure;

FIG. 6 is a schematic diagram of a relationship between a data unit and a data packet according to an embodiment of this disclosure;

FIG. 7 is a schematic flowchart of a method for processing haptic information according to an embodiment of this disclosure;

FIG. 8 is a schematic structural diagram of an apparatus for processing haptic information according to an embodiment of this disclosure;

FIG. 9 is a schematic structural diagram of an apparatus for processing haptic information according to an embodiment of this disclosure; and

FIG. 10 is a schematic structural diagram of an electronic device according to an embodiment of this disclosure.

### DESCRIPTION OF EMBODIMENTS

Technical solutions in this disclosure are described below with reference to the drawings in one or more embodiments of this disclosure. One or more embodiments described in this disclosure are merely some rather than all of the embodiments of this disclosure. All other embodiments obtained by a person of ordinary skill in the art based on this disclosure fall within the scope of this disclosure.

The terms such as “first” and “second” in the specification and claims of this disclosure and in the drawings are configured for distinguishing similar objects and not necessarily configured for describing any particular order or sequence. Data used in this way is exchangeable in a proper case, so that the embodiments of this disclosure described herein can be implemented in an order different from the order shown or described herein. In one or more embodiments of this disclosure, “B corresponding to A” represents that B is associated with A. In an implementation, B may be determined according to A. However, determining A according to B does not mean that B is determined according to only A. Instead, B may be determined according to A and/or other information. Moreover, the terms “include” and “have” and any variations are intended to cover non-exclusive inclusion. For example, a process, a method, a system, a product, or a server that includes a list of steps or units is not necessarily limited to those expressly listed steps or units, and may include other steps or units not expressly listed or inherent to such the process, the method, the product, or the device. In the description of this disclosure, unless otherwise stated, “a plurality of” means two or more.

In one or more embodiments of this disclosure, the term “module” or “unit” refers to a computer program having a predetermined function or a part of a computer program, and operates together with other relevant parts to achieve a predetermined objective, and may be all or partially implemented by using software, hardware (such as a processing circuit or a memory), or a combination thereof. Similarly, one processor (or a plurality of processors or memories) may be configured to implement one or more modules or units. In addition, each module or unit may be a part of an overall module or unit including a function of the module or the unit.

In one or more embodiments of this disclosure, the term “module” or “unit” refers to a computer program having a predetermined function or a part of a computer program, and operates together with other relevant parts to achieve a predetermined objective, and may be all or partially implemented by using software, hardware (such as a processing circuit or a memory), or a combination thereof. Similarly, one processor (or a plurality of processors or memories) may be configured to implement one or more modules or units. In addition, each module or unit may be a part of an overall module or unit including a function of the module or the unit.

Examples of terms involved in the aspects of the disclosure are briefly introduced. The descriptions of the terms are provided as examples only and are not intended to limit the scope of the disclosure.

In some aspects, haptic information presentation may be classified into the following categories: vibration tactility (or vibrotactile haptics), kinematic tactility (or kinesthetic haptics), and electro tactility (or electrotactile haptics). Further descriptions for these terms are as follows:

### 1. Vibration Tactility

The haptic presentation may be directly performed in a form of vibration, and a vibration having a specific frequency and intensity may be simulated by vibration of a motor of a terminal device. For example, in a shooting game, a particular effect may be simulated through vibration.

### 2. Kinematic Tactility

The kinematic tactility may be configured for simulating a movement state of an object, such as weight or pressure. For example, in a driving video game, when moving or operating a relatively heavy vehicle at a relatively high speed, a steering wheel may resist rotation. Such feedback may directly affect muscles of a user. In an example of a driving game, the kinematic tactility may cause a user to apply more force to obtain a desirable response from a steering wheel.

### 3. Electro Tactility

Electro tactility presentation of feedback information with a specific texture may be simulated through electrical stimulation. For example, haptic stimulation may be provided to nerve endings of the user's skin by using electrical pulses. The electro tactility presentation may create highly realistic experience for a user wearing a kit or a glove equipped with an electro tactility technology. Almost any feeling may be simulated through the electric pulses, including, for example, a temperature change, a pressure change, or a humidity feeling.

With the popularization of wearable devices and interactive devices, the haptic presentation perceptible to a user when consuming media content is no longer limited to basic vibration tactility, and may further include haptic presentation experience with all-round body perception, such as a vibration, a pressure, a speed, an acceleration, a temperature, a humidity, and/or a smell, that is more approximate to experience in the real world.

FIG. 1 is a schematic diagram of a haptic information representation and transmission system architecture 100 in a China national video coding standard (Audio Video Coding Standard, AVS). Referring to FIG. 1, a haptic information interchange format X may be generated based on a collected signal A or may be obtained by transcoding a related haptic signal format B. The haptic information interchange format X may be directly rendered and presented on a client, or may be encoded to generate a haptic information basic stream (which may also be referred to as a basic bit stream, bit stream) E. The haptic information basic stream is encapsulated based on a corresponding media container file format (such as, an ISO based media file format (ISOBMFF)) to obtain a group of sequences Fs of initialization segments and media segments configured for streaming transmission or a media file F configured for file playback. The sequence Fs configured for streaming transmission is combined with media presentation description information, and the Fs is transmitted to a player through a transmission mechanism. File decapsulation is configured to process a received file F′ or segment Fs′, extract a haptic information basic stream E′ and parse metadata, and then perform decoding to generate a haptic information interchange format X′, which may be finally rendered and presented by the client.

A haptic media interchange format is configured for describing a signal included in the haptic media. The haptic media interchange format defined by the haptic information representation and transmission system architecture 100 in the AVS as provided in FIG. 1 is in a form of a human-readable javascript object notation (JSON) file (e.g., a text-based interchange format file). However, the haptic information representation and transmission system architecture 100 in the AVS as provided in FIG. 1 does not specify in detail how to perform encoding through the haptic information interchange format X to obtain the bit stream (such as, a dashed-line box in FIG. 1). Therefore, if the haptic media interchange format in the form of the JSON file is encapsulated and transmitted, a problem that an internal memory and bandwidth usage need to be optimized exists.

Therefore, an embodiment of this disclosure provides a haptic media content processing method to encode an interchange format of a haptic information, thereby obtaining a binary bit stream corresponding to the target haptic information. Further, the binary bit stream may be encapsulated to obtain the media file including the haptic information. An embodiment of this disclosure provides a solution of encoding the interchange format of haptic information into a binary bit stream. In at least one aspect, data is organized and divided in the binary bit stream in a form of a data unit and a data packet, and one data unit includes one or more data packets. The solution provided in one or more embodiments of this disclosure facilitates saving of space occupied by the haptic media content.

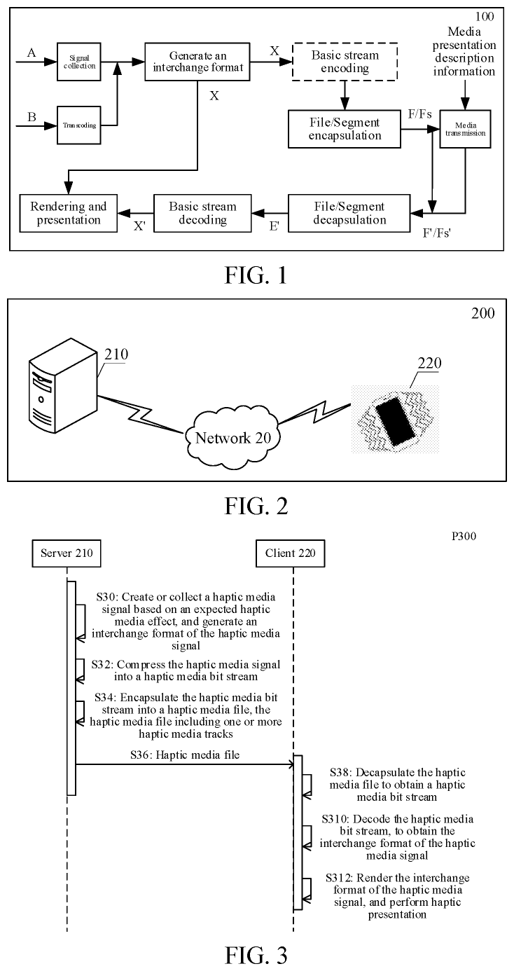

FIG. 2 is a schematic diagram of an application scenario 200 for processing haptic information according to an embodiment of this disclosure. Referring to FIG. 2, in the application scenario 200 for processing haptic information, a terminal 220 may be configured to implement haptic presentation, for example, vibration. Data transmission and interaction may be performed between a server 210 and the terminal 220 through a communication network 20. In some embodiments, the terminal 220 may be understood as a decapsulation device, and the server 210 may be understood as an encapsulation device.

In an implementation process, the terminal 220 may provide computing resources for running an algorithm model. For example, specifically, the terminal 220 may be a haptic feedback-related product, and a player end or another intermediate node of an immersive system, including, for example, a smartphone, a desktop computer, a mobile computing apparatus, a notebook (such as, laptop) computer, a tablet computer, a set-top box, a television, a camera, a display apparatus, a digital media player, a video game console, an on-board computer, a navigator, a digital phone, a video phone, a television set, a sensing device, and a server, which is not limited in this disclosure. In at least one aspect, the server 210 may be a server side of the immersive system, for example, an independent physical server, or may be a server cluster formed by a plurality of physical servers or a distributed system, or may be a cloud server that provides basic cloud computing services such as a cloud service, a cloud database, cloud computing, a cloud function, cloud storage, a network service, cloud communication, a middleware service, a domain name service, a security service, a content delivery network (CDN), and big data and an artificial intelligence platform. The communication network 20 may include wired or wireless communication manners for direct or indirect connection, which is not limited herein in this disclosure.

FIG. 2 is merely an example of an application scenario provided in an embodiment of this disclosure, and application scenarios in one or more embodiments of this disclosure include, but is not limited to, that shown in FIG. 2.

Based on the scenario shown in FIG. 2, a method P300 for processing haptic information shown in FIG. 3 may be performed. Referring to FIG. 3, the method P300 for processing haptic information includes S30 to S312.

In S30, the server 210 creates or collects a haptic media signal based on an expected haptic media effect, and generates an interchange format of the haptic media signal.

In S32, the server 210 compresses and encodes the haptic media signal into a haptic media bit stream according to a solution provided in an embodiment of this disclosure (such as a solution provided in an embodiment of FIG. 5).

In S34, the server 210 encapsulates the haptic media bit stream into a haptic media file, the haptic media file including one or more haptic media tracks.

In an embodiment, after determining the haptic media file, the server 210 may further slice the haptic media file into a plurality of haptic media file segments.

In S36, the server 210 transmits the haptic media file or the haptic media file segments to the terminal 220 to enable a client installed on the terminal to obtain the haptic media file or the haptic media file segments.

In S38, the client of the terminal 220 decapsulates the haptic media file, to obtain a haptic media bit stream.

In S310, the client of the terminal 220 decodes the haptic media bit stream according to the solution provided in one or more embodiments of this disclosure (such as a solution provided in an embodiment of FIG. 7) to obtain the interchange format of the haptic media signal.

In S312, the client of the terminal 220 renders the interchange format of the haptic media signal, and performs haptic presentation.

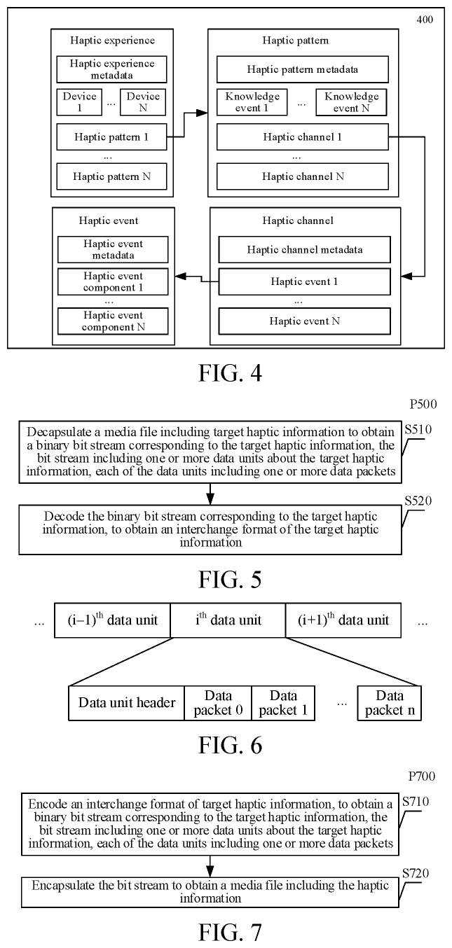

Before the technical solution in one or more embodiments of this disclosure is described in detail, a defined data structure configured for representing the haptic media in the related art is first introduced. FIG. 4 is a schematic diagram of a haptic information representation data structure 400 in the AVS. Referring to FIG. 4, the defined data structure configured for representing the haptic media in the related art is as follows:

A data structure at a highest level for haptic information representation is haptic experience (or also referred to as a haptic experience dataset in this disclosure), and is configured for describing all haptic experience information in a file or a bit stream. The haptic experience includes metadata information regarding the haptic experience, possible device information, and one or more haptic patterns.

The haptic pattern corresponds to a type of a haptic signal (for example, vibration, a pressure, or a temperature), and the haptic pattern includes metadata information regarding the haptic pattern, a knowledge haptic event that may be predefined, and one or more haptic channels.

The haptic channel includes all or some haptic signals of a corresponding haptic pattern, and the haptic channel includes metadata information regarding the haptic channel and one or more haptic events. Generally, haptic signals corresponding to different rendering devices in the same haptic pattern may be organized as different haptic channels.

The haptic event is a basic haptic signal unit, and the haptic event includes metadata information regarding the haptic event and a possible haptic event component. The haptic event component is a time domain component or a frequency domain component of the haptic event.
1. The data structure of the haptic experience is defined as in Table 1.

TABLE 1

| Attribute | Description |
|---|---|
| version | Indication of information on a standard version |
| | followed by the haptic experience. |
| creation_date | Indication of a creation time of the haptic experience. |
| description | Indication of description information of the haptic |
| | experience, which is user-defined. |
| timescale | Time scale of the haptic experience, which indicates |
| | a quantity of clock units included in a second. |
| devices | Device information element list, which indicates one or |
| | more pieces of device information regarding the |
| | haptic experience. |
| patterns | Haptic pattern element list, which indicates one or more |
| | haptic patterns included in the haptic experience. |

2. A data structure of attribute device information of the haptic experience is defined as in Table 2.

TABLE 2

| Attribute | Description |
|---|---|
| id | Indication of an identifier of a device |
| device_name | Indication of a name (human-readable) of a device |
| body_parts | Indication of a body part corresponding to a device |

3. A data structure of the haptic pattern is defined as in Table 3.

TABLE 3

| Attribute | Description |
|---|---|
| id | Indication of an identifier of the haptic pattern |
| pattern_type | Indication of a type of the haptic pattern, |
| | possible values of which are as follows: |
| | vibration tactility |
| | pressure |
| | an acceleration |
| | speed |
| | temperature |
| | electro tactility |
| refer_devices | Indication of a device corresponding to the |
| | haptic pattern, the field having a value |
| | corresponding to a device identifier defined |
| | in the device information. |
| event_semantics_flag | Indication of whether a haptic event |
| | corresponding to the haptic pattern has |
| | semantics. |
| event_semantics_type | Indication of a specification followed by |
| | the semantics of a haptic event, which |
| | field may have the following values: |
| | the semantics of the haptic event |
| | that follows a specification defined |
| | by this standard |
| | the semantics of the haptic event |
| | that follows a specification of |
| | an external standard |
| | the semantics of the haptic event |
| | that is user-defined |
| library_events | Knowledge haptic event element list, |
| | which indicates a knowledge haptic event |
| | included in the haptic pattern. |
| channels | Haptic channel element list, which indicates |
| | a haptic channel included in the haptic |
| | pattern. |

4. A knowledge haptic event.

The knowledge haptic event is a special haptic event, and a data structure thereof follows a data structure definition of the haptic event. The knowledge haptic event is usually a predefined haptic event that may be repeatedly cited to avoid repeated parsing of the same haptic event.
5. A data structure of the haptic channel is defined as in Table 4.

TABLE 4

| Attribute | Description |
|---|---|
| id | Indication of an identifier of the haptic channel. |
| description | Indication of a description of the haptic channel, |
| | which is user-defined. |
| refer_devices | Indication of a device corresponding to the haptic |
| | pattern, the field having a value corresponding to a |
| | device identifier defined in the device information. |
| gain | Indication of a gain of the haptic channel, the gain |
| | being applied to all events included in the current |
| | channel, and used for restoring a normalized signal |
| | value to an original signal value. |
| | V = gain * x |
| | where x is the normalized signal value. |
| events | Haptic event element list, which indicates haptic |
| | events included in a channel. |

6. A data structure of a haptic event is defined as in Table 5.

TABLE 5

| Attribute | Description |
|---|---|
| id | Indication of an identifier of the haptic event |
| effect_semantic | Indication of semantics of the haptic event. |
| | When a value of an event_semantics_flag field |
| | in a corresponding pattern is true, the |
| | attribute exists. |
| | The semantics of the haptic event is an event |
| | auxiliary information keyword that describes |
| | an intention of a content producer. |
| event_type | Indication of a type of the haptic event, which |
| | may have the following values: |
| | an instantaneous event |
| | a sustained event |
| | reference event |
| refer_library_event | When the type of the haptic event is the reference |
| | event, the attribute exists, which indicates a |
| | knowledge haptic event identifier corresponding |
| | to the reference event. |
| relative_time | Indication of a time offset of the haptic event. |
| duration | Indication of a duration of the haptic event, |
| | the attribute existing when an event type is |
| | the sustained event. |
| amplitude | Indication of a maximum signal amplitude value of |
| | the haptic event. |
| base_frequency | Indication of a signal reference frequency of the |
| | haptic event. |
| event_components | Haptic event component element list, which |
| | indicates a component of the haptic event which |
| | may be a time domain component or a frequency |
| | domain component of the haptic event. |

7. A data structure of an attribute of the haptic event component of the haptic event is defined as in Table 6.

TABLE 6

| Attribute | Description |
|---|---|
| refer_event_id | Identifier that indicates a haptic event |
| | to which the haptic event component belongs. |
| relative_time | Indication of a time offset of the haptic |
| | event component relative to the haptic event. |
| relative_amplitude | Indication of an amplitude value ratio of |
| | the haptic event component relative to the |
| | haptic event, which has a value range from 0 to 1. |
| relative_frequency | Indication of a frequency offset of the haptic |
| | event component relative to the haptic event. |

The technical solutions in one or more embodiments of this disclosure are described in detail below by using some of the embodiments. The following embodiments may be combined with each other, and same or similar concepts or processes may not be repeated in some embodiments.

FIG. 5 is a schematic flowchart of a method P500 for processing haptic information according to an embodiment of this disclosure. An execution subject of the method P500 may be an electronic device that decodes a haptic media bit stream, such as the terminal 220 in FIG. 2. Descriptions are provided below by using an example in which the execution subject is a decapsulation device. Referring to FIG. 5, the method P500 includes S510 and S520.

In S510, the decapsulation device decapsulates a media file including target haptic information to obtain a binary bit stream corresponding to the target haptic information, the bit stream including one or more data units regarding the target haptic information, and the data unit including one or more data packets. For example, a media file that includes a haptic experience dataset is obtained. In some examples, a bit stream corresponding to the haptic experience dataset is obtained by processing circuitry from the media file, the bit stream including one or more data units, and each one of the one or more data units including one or more data packets and a syntax structure that includes (i) a data unit type indicator indicating a type of the data unit and (ii) a unit-level timestamp indicating an offset time of the data unit from a start time of the haptic experience dataset.

In one or more embodiments of this disclosure, based on the haptic information representation data structure 400 in the AVS shown in FIG. 4, several descriptive fields are added, including field extension of a haptic media bit stream, to support the method operations in one or more embodiments of this disclosure.

The binary bit stream obtained through encoding and compressing via a haptic media interchange format is a self-contained transmission stream format including a series of data units (AHAS Unit), and each data unit (AHAS Unit) corresponds to a presentation time of the haptic media.

For example, FIG. 6 is a schematic diagram of a relationship between a data unit and a data packet according to an embodiment of this disclosure. Referring to FIG. 6, a binary bit stream includes: an (i−1)^{th} data unit (AHAS Unit (i−1)), an i^{th} data unit (AHAS Unit (i)), an (i+1)^{th} data unit (AHAS Unit (i+1)), and the like. Each data unit includes at least one data packet. As shown in FIG. 6, the i^{th} data unit (AHAS Unit (i)) includes a data unit header (AHAS Unit Header), a data packet 0 (AHAS Packet 0), a data packet 1 (AHAS Packet 1), a data packet 2 (AHAS Packet 2), . . . , and a data packet n (AHAS Packet n). Each data packet includes a haptic signal, or metadata, or auxiliary information of the haptic signal. Specific details are described in detail in the following embodiments.

From FIG. 6, data is organized and divided in a bit stream in forms of a data unit and a data packet in one or more embodiments of this disclosure. In addition, the data unit and the data packet are divided into different types, and the types of the data unit and the data packet determine a type of data they contain. In some examples, for each one of the one or more data units, the data unit type indicator includes a binary value indicating the type of the data unit being one of an initialization type, a silent type, a time domain type, or a spatial domain type. Table 7 shows types of data units and types of data packets that the data units contain according to an embodiment of this disclosure.

TABLE 7

| AHAS data unit | | Content in AHAS data |
|---|---|---|
| type | AHAS data packet type | packet |
| Initialization | First type including | Experience-related |
| type | haptic experience metadata | metadata is included. |
| | Second type including | Pattern-related |
| | haptic pattern metadata | metadata is included. |
| | Third type including | Channel-related |
| | haptic channel metadata | metadata is included. |
| | Fourth type including a | Signal data including a |
| | knowledge haptic event | knowledge haptic event. |
| | (including or not) | |
| | Fifth type including a | Check code information |
| | cyclic check code | is included. |
| | (including or not) | |
| Time domain | Seventh type including | Signal data of a haptic |
| type or | a haptic signal | event is included. |
| spatial domain | Fifth type including a | Check code information |
| type | cyclic check code | is included. |
| | (including or not) | |
| Silent type | Sixth type including | Silent time length |
| | silent information | information is included. |

From Table 7, a data unit is classified into at least one of the following types:

### 1. Data Unit of the Initialization Type:

The data unit of the initialization type includes one data packet of the first type, one or more data packets of the second type, one or more data packets of the third type, zero or one or more data packets of the fourth type, and zero or one data packet of the fifth type. If a data packet of the fourth type exists in a bit stream, the data unit of the initialization type necessarily includes the data packet of the fourth type.

### 2. Data Unit of the Time Domain Type or the Spatial Domain Type:

The data unit of the time domain type or the spatial domain type includes one or more data packets of the seventh type, and zero or one data packet of the fifth type.

### 3. Data Unit of the Silent Type:

The data unit of the silent type includes a data packet of the sixth type.

After the relationship between the data unit and the data packet, the types of the data unit and the types of the data packet in one or more embodiments of this disclosure are introduced, syntax structures of the bit stream, the data unit, and the data packet are introduced below through Table 8 to Table 10, respectively. In an embodiment of this disclosure, a syntax and semantics of the bit stream are shown in Table 8.

TABLE 8

| | | |
|---|---|---|
| Syntax | Quantity of bits | Mnemonic |

```
avsHapticStream( )
{
  while (endOfStream( ) != 1) {
    avsHapticUnit( );
  }
}
```

The endOfStream( ) is a function for determining whether a data unit in a bit stream ends, and if the data unit in the bit stream ends, the function returns 1; and if the data unit in the bit stream does not end, the function returns 0.

In an embodiment of this disclosure, a syntax and semantics of a data unit (AHAS Unit) are shown in Table 9. The quantity of bits shown in Table 9 is example data, or may be another value, which is not limited in this disclosure.

TABLE 9

| Syntax | Quantity of bits | Mnemonic |
|---|---|---|
| avsHapticUnit( ) | | |
| { | | |
| AHASUnitType; | 3 | uimsbf |
| AHASUnitDependency; | 1 | bool |
| AHASUnitLayerFlag | 1 | bool |
| if(AHASUnitLayerFlag){ | | |
| AHASLayer} | 3 | uimsbf |
| else{ | | |
| reserved} | 3 | uimsbf |
| AHASUnitTimestamp; | 32 | uimsbf |
| AHASUnitLength; | 32 | uimsbf |
| while (endOfUnit( ) != 1) { | | |
| avsHapticPacket( ); | | |
| } | | |
| } | | |

Referring to Table 9, the AHASUnitType represents a type of a data unit. In one or more embodiments of this disclosure, a different type of a data unit corresponds to a different binary value. Referring to Table 9, a quantity of bits occupied by the type of the data unit is 3. For example, the type of the data unit that is the silent type may be represented as “100”. For example, a binary value meaning of the field may be shown in Table 9.1.

TABLE 9.1

| AHASUnitType | Binary | |
|---|---|---|
| (a type of a data unit) | value | Note |
| UNITTYPE_INIT | 0 | Initialization type |
| UNITTYPE_TEMPORAL | 1 | Time domain type |
| UNITTYPE_SPATIAL | 2 | Spatial domain type |
| UNITTYPE_SILENT | 3 | Silent type |
| Reserved | 4 to 7 | |

Referring to Table 9, the AHASUnitDependency represents a decoding dependency indicator.

If a value of the field is a first target value, it indicates that a current data unit does not depend on another data unit of the same type during decoding; and if the value of the field is not the first target value, it indicates that the current data unit depends on the another data unit of the same type during decoding.

In some embodiments, the first target value may be “0”, a value that is not the first target value may be specifically “1”. Because the data unit of the initialization type and the data unit of the silent type do not depend on another data unit of the same type during decoding, values of the fields in the data unit of the initialization type and the data unit of the silent type are 0.

If a data unit of a time domain or spatial domain type follows the data unit of the initialization type and a value of an AHASUnitDependency field of the data unit of the time domain or spatial domain type is the first target value (such as, 0), it may be considered that the data unit of the initialization type may be used as a decoding initiation unit, namely, a unit from which decoding of a bit stream may be directly started, also namely, a random access point for decoding the bit stream. In an embodiment, a current bit stream may be decoded directly starting from the data unit of the initialization type. The first target value is not limited in this disclosure.

Referring to Table 9, the AHASUnitLayerFlag represents a level indicator.

The level indicator is represented through a binary value. When a value of the field is a second target value, it indicates that a level of a data unit is not indicated. When the value of the field is not the second target value, it indicates that the level of the data unit is indicated. In an embodiment, the second target value may be “0”, and a value that is not the second target value may be “1”. Therefore, when the value of the level indicator AHASUnitLayerFlag is 0, it indicates that the level of the data unit is not indicated. When the value of the field is 1, it indicates that the level of the data unit is indicated. Certainly, the second target value is not limited in this disclosure.

Referring to Table 9, the AHASLayer represents a level identifier of a data unit.

In one or more embodiments of this disclosure, the level identifier is also represented through a binary value. In addition, a priority of the data unit may be determined through a value of the level identifier.

In some embodiments, a smaller value of the field represents a higher priority of the data unit. Otherwise, a larger value of the field represents a lower priority of the data unit. In some other embodiments, alternatively, the larger value of the AHASLayer field represents the higher priority of the data unit. Otherwise, the smaller value of the field represents the lower priority of the data unit. This is not limited in this disclosure.

Referring to Table 9, the AHASUnitTimestamp represents a first offset timestamp. A different timestamp corresponds to a different binary value. In an embodiment shown in Table 9, the first offset timestamp may occupy 32 bits.

The first offset timestamp represents an offset time of a data unit relative to a start time of haptic experience, which is in units of clocks. A quantity of clocks included in a second is specified by a timescale field in experience metadata (e.g., metadata of a haptic experience dataset). For example, a ratio of the first offset timestamp AHASUnitTimestamp to the timescale is a quantity of elapsed seconds of haptic experience.

For data units of different types, a value of the field may follow the following constraint:
for a data unit of an initialization type, the field has no practical meaning;
for a data unit of a silent type, the field is to be greater than a timestamp of any data packet in a data unit of a time domain or spatial domain type preceding the data unit of the silent type.
for a data unit of a time domain type or a spatial domain type, a timestamp of any data packet included in an i^{th} data unit is to be less than a timestamp of any data packet included in an (i+1)^{th} data unit. In some embodiments, the field is to be a minimum value of timestamps of M data packets included in the field. In some other embodiments, the field is to be a maximum value of the timestamps of the M data packets included in the field.

The first offset timestamp may be configured for implementing random access of a haptic signal during transmission. Specific implementations are described in detail in subsequent embodiments regarding a second offset timestamp.

Referring to Table 9, the AHASUnitLength represents a quantity of bytes of all data packets in a data unit. A different quantity of bytes corresponds to a different binary value. In an embodiment shown in Table 9, a quantity of bytes of all the data packets in the data unit may occupy 32 bits.

Referring to Table 9, the endOfUnit ( ) is a function for determining whether a data packet in a data unit ends, and if the data packet in the data unit ends, the function returns 1; and if the data unit does not end, the function returns 0. For example, after AHASUnitLength bytes of data packet data included in a data packet is parsed, a data unit ends.

Next, a syntax and semantics of a data unit (AHAS Packet) are introduced through Table 10. A quantity of bits shown in Table 10 is provided as a non-limiting example.

TABLE 10

| Syntax | Quantity of bits | Mnemonic |
|---|---|---|
| avsHapticPacket( ) | | |
| { | | |
| AHASPacketType; | 4 | uimsbf |
| AHASPacketLength; | 20 | uimsbf |
| if(AHASPacketType==6){ | | |
| AHASPacketTimestamp;} | 24 | uimsbf |
| AHASPacketPayload(AHASPacketType); | | |
| byteAlignment( ) | | |
| } | | |

Referring to Table 10, the AHASPacketType represents a type of a data packet. In one or more embodiments of this disclosure, different types of data packets correspond to different binary values. Referring to Table 10, a quantity of bits occupied by the type of the data packet is 4. For example, the type of the data packet is a sixth type including silent information, and may be represented as “0110”. For example, a binary value meaning of the field may be shown in Table 10.1.

TABLE 10.1

| AHASPacketType (a type | Val- | |
|---|---|---|
| of a data packet) | ue | Note |
| PACTYPE_METADATAEXPERI- | 0 | First type including |
| ENCE | | haptic experience |
| | | metadata |
| PACTYPE_METADATAPATTERN | 1 | Second type including |
| | | haptic pattern |
| | | metadata |
| PACTYPE_METADATACHANNEL | 2 | Third type including |
| | | haptic channel |
| | | metadata |
| PACTYPE_LIBRARYEVENTS | 3 | Fourth type including |
| | | a knowledge haptic |
| | | event |
| PACTYPE_CRC | 4 | Fifth type including |
| | | a cyclic check code |
| PACTYPE_SILENTINFO | 5 | Sixth type including |
| | | silent information |
| PACTYPE_DATA | 6 | Seventh type including |
| | | a haptic signal |
| Reserved | 7 to 15 | |

Referring to Table 10, the AHASPacketLength is used for indicating a quantity of bytes of a payload of a data packet, namely, a quantity of bytes of the AHASPacketPayload. In one or more embodiments of this disclosure, a quantity of bytes of the payload of the data packet may be represented through a binary value. Referring to Table 10, a quantity of bits occupied by the quantity of bytes of the payload of the data packet is 20.

Referring to Table 10, the AHASPacketTimestamp represents a second offset timestamp. A different timestamp corresponds to a different binary value. In an embodiment shown in Table 10, the second offset timestamp may occupy 24 bits.

The second offset timestamp is used for representing an offset, in units of clocks, relative to a first timestamp of a data unit where the data packet is located. A quantity of clocks included in a second is specified by a timescale field in experience metadata (e.g., metadata of a haptic experience dataset). In at least one aspect, in some embodiments, the second offset timestamp AHASPacketTimestamp represents a minimum value of timestamps of all haptic events included in the data packet. In some other embodiments, the second offset timestamp AHASPacketTimestamp represents a maximum value in the timestamps of all the haptic events included in the data packet.

In one or more embodiments of this disclosure, a timestamp of a current haptic signal data packet may be determined based on the second offset timestamp of the data packet and the first offset timestamp of the data unit where the data packet is located.

In a case that the first offset timestamp AHASUnitTimestamp represents a minimum value of timestamps of all data packets included in the first offset timestamp, AHASUnitTimestamp+AHASPacketTimestamp may be determined as the timestamp of the current haptic signal data packet. In a case that the first offset timestamp AHASUnitTimestamp represents a maximum value of the timestamps of all the data packets included in the first offset timestamp, AHASUnitTimestamp−AHASPacketTimestamp may be determined as the timestamp of the current haptic signal data packet.

According to the solution provided in one or more embodiments of this disclosure, the timestamp of the current haptic signal data packet may be determined through the second offset timestamp of the current data packet and the first offset timestamp of the data unit where the data packet is located, thereby supporting random access of a haptic signal during transmission.

Referring to Table 10, the byteAlignment( ) is a function for determining byte alignment. If data included in a current data packet is an integer quantity of bytes, it returns 0; and if the data included in the current data packet is not an integral quantity of bytes, it returns 0 after the last byte is supplemented.

Referring to Table 10, a syntax of the AHASPacketPayload may be introduced with reference to Table 10.2.

TABLE 10.2

| | | |
|---|---|---|
| | Quantity | |
| Syntax | of bits | Mnemonic |

```
avsPacketPayload(AHASPacketType)
{
  switch (AHASPacketType) {
  case PACTYPE_METADATAEXPERIENCE:
  readMetadataExperience( );
  break;
  case PACTYPE_METADATAPATTERN:
  readMetadataPattern( );
  break;
  case PACTYPE_METADATACHANNEL:
  readMetadataChannel( );
  break;
  case PACTYPE_DATA:
  readData ( );
  break;
  case PACTYPE_LIBRARYEFFECTS:
  readLibrary( );
  break;
  case PACTYPE_SILENTINFO:
  readSilentInfo( );
  break;
  case PACTYPE_CRC:
  readCRC( );
  break;
  }
}
```

According to different types of data packets, in a process of executing the syntax in Table 10.2, a syntax of a payload of a data packet of a corresponding type shown in one of Table 10.2-A to Table 10.2-G is executed. Quantities of bits shown in Table 10.2-A to Table 10.2-G are example data, and may also be other values, which is not limited in this disclosure.

In a case that a type of a data packet is a first type including haptic experience metadata (e.g., metadata of a haptic experience dataset), in a process of executing the syntax in Table 10.2, a syntax of a payload of a data packet shown in Table 10.2-A is executed.

TABLE 10.2-A

| Syntax | Quantity of bits | Mnemonic |
|---|---|---|
| readMetadataExperience( ) | | |
| { | | |
| version; | 8 | uimsbf |
| dateLength; | 8 | uimsbf |
| date; | dateLength*8 | string |
| descriptionLength; | 8 | uimsbf |
| description; | descriptionLength*8 | string |
| timescale | 16 | uimsbf |
| patternCount; | 8 | uimsbf |
| deviceCount; | 8 | uimsbf |
| for (i = 0; i < deviceCount; i++) { | | |
| readDevice( ); | | |
| } | | |
| } | | |

In a case that the type of the data packet is the first type including the haptic experience metadata, the payload of the data packet includes one or more of the following fields shown in Table 10.2-A. Each field in Table 10.2-A may be represented through a binary value. In at least one aspect, specific indication information of each field is as follows:

The Version is used for indicating information on a standard version followed by haptic experience; and a binary value used for representing the Version may occupy 8 bits.

The dateLength is used for indicating a string length of a creation date of haptic experience; and a binary value configured for representing the dateLength may occupy 8 bits.

The Date is used for indicating a creation date of haptic experience; and a binary value configured for representing the Date may occupy dateLength×8 bits.

The descriptionLength is used for indicating a string length of a haptic experience description; and a binary value used for representing the descriptionLength may occupy 8 bits.

The Description is used for indicating a haptic experience description; and a binary value used for representing the Description may occupy descriptionLength×8 bits.

The Timescale is used for indicating a time scale of a haptic experience, and a value of the field represents a quantity of clock units included in a second; and a binary value used for representing the Timescale may occupy 16 bits.

The patternCount is used for indicating a quantity of patterns included in haptic experience; and a binary value used for representing the patternCount may occupy 8 bits.

The deviceCount is used for indicating a quantity of devices corresponding to haptic experience; and a binary value used for representing the deviceCount may occupy 8 bits.

For a syntax of the readDeviceo in Table 10.2-A, reference may be made to Table 10.2-A1.

TABLE 10.2-A1

| Syntax | Quantity of bits | Mnemonic |
|---|---|---|
| readDevice( ) | | |
| { | | |
| deviceId; | 8 | uimsbf |
| nameLength | 8 | uimsbf |
| deviceName; | nameLength *8 | string |
| bodyPartFlag | 1 | bool |
| If(bodyPartFlag == 1){ | | |
| bodyParts;} | 8 | uimsbf |
| } | | |

The payload of the foregoing data packet further includes: one or more of the following fields shown in Table 10.2-A1 about a j^{th} device. Each field in Table 10.2-A1 may be represented through a binary value. In at least one aspect, specific indication information of each field is as follows:

The deviceId is used for indicating an identifier of the j^{th} device; and a binary value used for representing the deviceId may occupy 8 bits.

The nameLength is used for indicating a string length of a name of the jth device; and a binary value used for representing the nameLength may occupy 8 bits.

The deviceName is used for indicating the name of the j^{th} device readable by humans; and a binary value used for representing the deviceName may occupy 8 bits.

The bodyPartFlag is used for indicator of whether the device corresponds to a body part; and a binary value used for representing the bodyPartFlag may occupy 1 bit. For example, the value that is 1 indicates information on a body part corresponding to the device. The value that is 0 does not indicate information on the body part corresponding to the device.

The bodyParts is used for indicating a body part corresponding to the device; and a binary value used for representing the bodyParts may occupy 8 bits.

In a case that the type of the data packet is the second type including the haptic pattern metadata, in a process of executing the syntax in Table 10.2, a syntax of the payload of the data packet shown in Table 10.2-B is executed.

TABLE 10.2-B

| | Quantity | |
|---|---|---|
| Syntax | of bits | Mnemonic |
| readMetadataPattern( ) | | |
| { | | |
| id; | 8 | uimsbf |
| patternType; | 8 | uimsbf |
| semanticisFlag | 1 | boolean |
| if(semanticisFlag){ | | |
| sementicsType} | 8 | uimsbf |
| referenceDeviceCount; | 8 | uimsbf |
| for (i = 0; i < referenceDeviceCount; i++) { | | |
| referenceDeviceId; | 8 | uimsbf |
| } | | |
| channelCount; | 16 | uimsbf |
| } | | |

In a case that the type of the data packet is the second type including the haptic pattern metadata, the payload of the data packet includes one or more of the following fields shown in Table 10.2-B. Each field in Table 10.2-B may be represented through a binary value. In at least one aspect, specific indication information of each field is as follows:

The Id is used for indicating an identifier of a haptic pattern; and a binary value used for representing the Id may occupy 8 bits.

The patternType is used for indicating a type of the haptic pattern; and a binary value configured for representing the patternType may occupy 8 bits. For example, a type of a data pattern is an acceleration, which may be represented as “0000 0010”. For example, a meaning of the binary value of the field may be shown in Table 10.2-B1.

TABLE 10.2-B1

| Value of patternType | Meaning |
|---|---|
| 0 | Vibration tactility |
| 1 | Pressure |
| 2 | Acceleration |
| 3 | Speed |
| 4 | Temperature |
| 5 | Electro tactility |
| 6 to 255 | Reserved |

The semanticisFlag is an indicator of whether semantics exists for a haptic event corresponding to the haptic pattern; and a binary value used for representing the semanticisFlag may occupy 1 bit. For example, when the value is 1, it indicates that the haptic event corresponding to the haptic pattern has semantics. When the value is 0, it indicates that the haptic event corresponding to the haptic pattern has no semantics.

The sementicsType is used for representing an indicator of a specification followed by semantics of a haptic event; and a binary value used for representing the sementicsType may occupy 8 bits. For example, when the value is 0, it indicates that the semantics of the haptic event follows a specification defined by this standard. When the value is 1, it indicates that the semantics of the haptic event follows a specification of an external standard. When the value is 2, it indicates that the semantics of the haptic event is user-defined.

The referenceDeviceCount is used for representing a quantity of devices corresponding to a haptic pattern; and a binary value configured for representing the referenceDeviceCount may occupy 8 bits.

The referenceDeviceId is used for indicating an identifier of a device corresponding to a haptic pattern; and a binary value used for representing the referenceDeviceId may occupy 8 bits.

The channelCount is used for indicating a quantity of haptic channels included in a haptic pattern; and a binary value used for representing the channelCount may occupy 16 bits.

In a case that the type of the data packet is the third type including the haptic channel metadata, in a process of executing the syntax in Table 10.2, a syntax of the payload of the data packet shown in Table 10.2-C is executed.

TABLE 10.2-C

| Syntax | Quantity of bits | Mnemonic |
|---|---|---|
| readMetadataChannel( ) | | |
| { | | |
| id; | 16 | uimsbf |
| perceptionId; | 8 | uimsbf |
| descriptionLength; | 8 | uimsbf |
| description; | descriptionLength*8 | string |
| gain; | 32 | imsbf |
| referenceDeviceCount; | 8 | uimsbf |
| for (i = 0; i < referenceDeviceCount; | | |
| i++) { | | |
| referenceDeviceId; | 8 | uimsbf |
| } | | |
| eventsCount; | 16 | uimsbf |
| } | | |

In a case that the type of the data packet is the third type including the haptic channel metadata, the payload of the data packet includes one or more of the following fields shown in Table 10.2-C. Each field in Table 10.2-C may be represented through a binary value. In at least one aspect, specific indication information of each field is as follows:

The Id is used for indicating an identifier of a haptic channel; and a binary value used for representing the Id may occupy 16 bits.

The perceptionId is used for indicating an identifier of a haptic pattern corresponding to a haptic channel; and a binary value configured for representing the perceptionId may occupy 8 bits.

The descriptionLength is used for indicating a string length of a haptic channel description; and a binary value configured for representing the descriptionLength may occupy 8 bits.

The Description is configured for indicating the haptic channel description; and a binary value configured for representing the Description may occupy 8×descriptionLength bits.

The Gain is used for indicating a gain of a haptic channel; and a binary value used for representing the Gain may occupy 32 bits. In at least one aspect, 2-31 is used as a unit. The Gain is applied to all events included in a current channel, and is used for restoring a normalized signal value to an original signal value.

The referenceDeviceCount is used for indicating a quantity of devices corresponding to a haptic channel; and a binary value configured for representing the referenceDeviceCount may occupy 8 bits.

The referenceDeviceId is configured for indicating an identifier of a device corresponding to a haptic channel; and a binary value configured for representing the referenceDeviceId may occupy 8 bits.

The eventsCount is used for indicating a quantity of haptic events included in a haptic channel; and a binary value configured for representing the eventsCount may occupy 16 bits.

In a case that the type of the data packet is the seventh type including the haptic signal, in a process of executing the syntax in Table 10.2, a syntax of the payload of the data packet shown in Table 10.2-D is executed.

TABLE 10.2-D

| Syntax | Quantity of bits | Mnemonic |
|---|---|---|
| readData( ) { | | |
| packetDependency; | 1 | bool |
| perceptionId; | 8 | uimsbf |
| channelId; | 8 | uimsbf |
| eventsCount; | 16 | uimsbf |
| for (i = 0; i < eventsCount; i++) { | | |
| readEvent( ); | | |
| } | | |
| } | | |

In a case that the type of the data packet is the seventh type including the haptic signal, the payload of the data packet includes one or more of the following fields shown in Table 10.2-D. Each field in Table 10.2-D may be represented through a binary value. In at least one aspect, specific indication information of each field is as follows:

The packetDependency represents an indicator of whether a current data packet depends on another data packet of the same type during decoding; and a binary value used for representing the packetDependency may occupy 1 bit. For example, when a value of the field is 0, it indicates that the current data packet does not depend on another data packet of the same type during decoding. When a value of the field is 1, it indicates that the current data packet depends on another data packet of the same type during decoding.

The perceptionId is used for indicating an identifier of a haptic pattern corresponding to a corresponding haptic event in a data packet; and a binary value used for representing the perceptionId may occupy 8 bits.

The channelId is used for indicating an identifier of a haptic channel corresponding to a corresponding haptic event in a data packet; and a binary value configured for representing the channelId may occupy 8 bits.

The eventsCount is used for indicating a quantity of haptic events corresponding to a data packet; and a binary value configured for representing the eventsCount may occupy 16 bits.

For a syntax of readEvent( ) in Table 10.2-D, reference may be made to Table 10.2-D1.

TABLE 10.2-D1

| Syntax | Quantity of bits | Mnemonic |
|---|---|---|
| readEvent( ) { | | |
| eventId | 16 | uimsbf |
| eventType; | 4 | uimsbf |
| eventSementicsFlag | 1 | bool |
| if (eventSementicsFlag) { | | |
| semanticKeywords | 12 | uimsbf |
| } | | |
| if (eventType == 2) { | | |
| referEventId; | 16 | uimsbf |
| } | | |
| relativePosition | 32 | imsbf |
| if (eventType == 1) { | | |
| duration; | 32 | uimsbf |
| } | | |
| amplitude | 8 | uimsbf |
| baseFrequency | 16 | uimsbf |
| numComponents | 16 | uimsbf |
| for (i = 0; i < numComponents; i++) { | | |
| readEventComponent( ); | | |
| } | | |
| } | | |

The payload of the foregoing data packet further includes: one or more of the following fields about an m^{th} haptic event shown in Table 10.2-D1. Each field in Table 10.2-D1 may be represented through a binary value. In at least one aspect, specific indication information of each field is as follows:

The eventId is used for indicating an identifier of a haptic event; and a binary value used for representing the eventId may occupy 16 bits.

The eventType is used for indicating a type of a haptic event; and a binary value used for representing the eventType may occupy 4 bits. For example, when a value of the field is 0, it indicates that the event is an instantaneous event, when the value of the field is 1, it indicates that the event is a sustained event, and when the value of the field is 2, it indicates that the event is a reference event.

The eventSementicsFlag is used for representing a value of an indicator indicating whether semantics of the haptic event is indicated; and a binary value used for representing the eventSementicsFlag may occupy 1 bit. For example, when the value is 0, semantics of a haptic event is not indicated. When the value is 1, semantics of a haptic event is indicated.

The semanticKeywords represents semantic information of a haptic event; and a binary value used for representing the semanticKeywords may occupy 12 bits. The semantics of the haptic event is an event auxiliary information keyword that describes an intention of a content producer.

The referEventId is used for indicating a knowledge haptic event identifier corresponding to a reference event; and a binary value used for representing the referEventId may occupy 16 bits.

The relativePosition is used for indicating a time or space offset of a haptic event; and a binary value used for representing the relativePosition may occupy 32 bits.

The Duration is used for indicating a duration of a haptic event, and the attribute exists when an event type is a sustained event; and a binary value used for representing the Duration may occupy 32 bits.

The Amplitude is used for indicating a maximum signal amplitude value of a haptic event; and a binary value used for representing the Amplitude may occupy 8 bits.

The baseFrequency is used for indicating a signal reference frequency of a haptic event; and a binary value used for representing the baseFrequency may occupy 16 bits.

The numComponents is used for indicating a quantity of a haptic event component, and the haptic event component may be a time domain component or a frequency domain component of a haptic event; and a binary value used for representing the numComponents may occupy 16 bits.

For a syntax of readEventComponent( ) in Table 10.2-D1, reference may be made to Table 10.2-1D2.

TABLE 10.2-D2

| Syntax | Quantity of bits | Mnemonic |
|---|---|---|
| readEventComponent( ) { | | |
| refer_event_id | 16 | uimsbf |
| position_flag | 1 | bool |
| amplitude_flag | | |
| frequency_flag | | |
| if(position_flag == 1){ | | |
| relative_position;} | 16 | uimsbf |
| if(relative_amplitude == 1){ | | |
| relative_amplitude; } | 16 | uimsbf |
| if(relative_frequency == 1){ | | |
| relative_frequency; } | 16 | uimsbf |
| } | | |

The payload of the foregoing data packet further includes: one or more of the following fields about a k^{th} haptic event component shown in Table 10.2-1D2. Each field in Table 10.2-1D2 may be represented through a binary value. In at least one aspect, specific indication information of each field is as follows:

The refer_event_id is used for indicating an identifier of a haptic event to which a haptic event component belongs; and a binary value used for representing the refer_event_id may occupy 16 bits.

The position flag is used for representing an indicator of whether a haptic event component includes a time-space domain offset; and a binary value used for representing the position flag may occupy 1 bit. For example, when the value of position flag is 1, it indicates that the haptic event component includes the time-space domain offset, and when the value is 0, it indicates that the haptic event component does not include the time-space domain offset.

The amplitude flag is used for representing an indicator of whether a haptic event component includes an amplitude value offset; and a binary value used for representing the amplitude flag may occupy 1 bit. For example, when the value of the amplitude flag is 1, it indicates that the haptic event component includes the amplitude value offset, and when the value is 0, it indicates that the haptic event component does not include the amplitude value offset.

The frequency_flag is used for representing an indicator of whether a haptic event component includes a frequency offset; and a binary value used for representing the frequency_flag may occupy 1 bit. For example, when the value of the frequency_flag is 1, it indicates that the haptic event component includes the frequency offset, and when the value is 0, it indicates that the haptic event component does not include a frequency offset.

The relative_position is used for representing a time or space offset of a haptic event component relative to a haptic event; and a binary value used for representing the relative_position may occupy 16 bits.

The relative_amplitude is used for representing an amplitude value ratio of a haptic event component relative to a haptic event, and is in a value range of 0 to 215 with 2-15 as a unit; and a binary value used for representing the relative_amplitude may occupy 16 bits.

The relative_frequency is used for representing a frequency offset of a haptic event component relative to a haptic event; and a binary value used for representing the relative_frequency may occupy 16 bits.

In a case that the type of the data packet is the fourth type including a knowledge haptic event, in a process of executing the syntax in Table 10.2, a syntax of the payload of the data packet shown in Table 10.2-E is executed.

TABLE 10.2-E

| Syntax | Quantity of bits | Mnemonic |
|---|---|---|
| readLibrary ( ) { | | |
| patternId; | 8 | uimsbf |
| eventsCount; | 16 | uimsbf |
| for (i = 0; i < eventsCount; i++) { | | |
| readLibraryEvent( ); | | |
| } | | |
| } | | |

In a case that the type of the data packet is the fourth type including the knowledge haptic event, the payload of the data packet includes one or more of the following fields shown in Table 10.2-E. Each field in Table 10.2-E may be represented through a binary value. In at least one aspect, specific indication information of each field is as follows:

The patternId is used for representing an identifier of a haptic pattern corresponding to a knowledge haptic event; and a binary value used for representing the patternId may occupy 8 bits.

The eventsCount is used for representing a quantity of knowledge haptic events corresponding to a data packet; and a binary value used for representing the eventsCount may occupy 16 bits.

For a syntax of readLibraryEvent( ) in Table 10.2-E, reference may be made to Table 10.2-E1.

TABLE 10.2-E1

| Syntax | Quantity of bits | Mnemonic |
|---|---|---|
| readLibraryEvent( ) { | | |
| eventId | 16 | uimsbf |
| eventType; | 4 | uimsbf |
| eventSementicsFlag | 1 | bool |
| if (eventSementicsFlag) { | | |
| semanticKeywords | 12 | uimsbf |
| } | | |
| relativePosition | 32 | imsbf |
| if (eventType == 1) { | | |
| duration; | 32 | uimsbf |
| } | | |
| amplitude | 8 | uimsbf |
| baseFrequency | 16 | uimsbf |
| numComponents | 16 | uimsbf |
| for (i = 0; i < numComponents; i++) { | | |
| readEventComponent( ); | | |
| } | | |
| } | | |

The payload of the foregoing data packet further includes: one or more of the following fields about an h^{th} knowledge haptic event shown in Table 10.2-E1. Each field in Table 10.2-E1 may be represented through a binary value. In at least one aspect, specific indication information of each field is as follows:

The eventId is used for representing an identifier of a knowledge haptic event; and a binary value used for representing the eventId may occupy 16 bits.

The eventType is used for representing a type of the knowledge haptic event; and a binary value used for representing the eventType may occupy 4 bits. For example, when a value of the field is 0, it indicates that an event is an instantaneous event. When the value of the field is 1, it indicates that the event is a sustained event.

The eventSementicsFlag is an indicator used for representing whether semantics of a knowledge haptic event is indicated; and a binary value used for representing the eventSementicsFlag may occupy 1 bit. For example, when the value is 0, semantics of a knowledge haptic event is not indicated. When the value is 1, the semantics of the knowledge haptic event is indicated.

The semanticKeywords is used for representing semantic information of an event; and a binary value used for representing the semanticKeywords may occupy 12 bits. The semantics of the knowledge haptic event is an event auxiliary information keyword that describes an intention of a content producer.

The relativePosition is used for representing a time or space offset of a knowledge haptic event; and a binary value used for representing the relativePosition may occupy 32 bits.

The Duration is used for representing a duration of a knowledge haptic event, and the attribute exists when an event type is a sustained event; and a binary value used for representing the Duration may occupy 32 bits.

The Amplitude is used for representing a maximum signal amplitude value of a knowledge haptic event; and a binary value used for representing the Amplitude may occupy 8 bits.

The baseFrequency is used for representing a signal reference frequency of a knowledge haptic event; and a binary value used for representing the baseFrequency may occupy 16 bits.

The numComponents is used for representing a quantity of a knowledge haptic event component, and the knowledge haptic event component may be a time domain component or a frequency domain component of a knowledge haptic event; and a binary value used for representing the numComponents may occupy 16 bits.

For a syntax of readEventComponent( ) in Table 10.2-E1, reference may be made to Table 10.2-D2. Details are not described herein again.

In a case that the type of the data packet is the sixth type including the silent data, in a process of executing the syntax in Table 10.2, a syntax of the payload of the data packet shown in Table 10.2-F is executed.

TABLE 10.2-F

| Syntax | Quantity of bits | Mnemonic |
|---|---|---|
| readSilentInfo ( ) { | | |
| silentDuration; | 16 | uimsbf |
| } | | |

In a case that the type of the data packet is the sixth type including the silent data, the payload of the data packet includes a field shown in Table 10.2-F. Afield in Table 10.2-F may be represented through a binary value. In at least one aspect, specific indication information of the field is as follows:

The silentDuration is used for representing a length of a silent time, and is used in a unit of a time scale; and a binary value used for representing the silentDuration may occupy 16 bits.

In a case that the type of the data packet is the fifth type including the cyclic check code, in a process of executing the syntax in Table 10.2, a syntax of the payload of the data packet shown in Table 10.2-G is executed.

TABLE 10.2-G

| Syntax | Quantity of bits | Mnemonic |
|---|---|---|
| readCRC( ) | | |
| { | | |
| CRCType | 8 | uimsbf |
| if (CRCType == 0) { | | |
| CRC16Value; | 16 | uimsbf |
| } else if (CRCType == 1) { | | |
| CRC32Value; | 32 | uimsbf |
| } else if (CRCType == 2) { | | |
| protectedPacketsCount; | 8 | uimsbf |
| CRC16Value; | 16 | uimsbf |
| } else if (CRCType == 3) { | | |
| protectedPacketsCount; | 8 | uimsbf |
| CRC32Value; | 32 | uimsbf |
| } | | |
| } | | |

In a case that the type of the data packet is the fifth type including the cyclic check code, the payload of the data packet includes one or more of the following fields shown in Table 10.2-G. Each field in Table 10.2-G may be represented through a binary value. In at least one aspect, specific indication information of each field is as follows:

The CRCType is used for representing a type of a cyclic check code; and a binary value used for representing the CRCTypey may occupy 8 bits. For example, when the value is 0, it indicates that the cyclic check code is a 16-bit check code, and a data packet protected by the cyclic check code is a data packet after a data packet of the cyclic check code. When the value is 1, it indicates that the cyclic check code is a 32-bit check code, and a data packet protected by the cyclic check code is a data packet after a data packet of the cyclic check code. When the value is 2, it indicates that the cyclic check code is a 16-bit check code, and a range of a data packet protected by the cyclic check code is protectedPacketsCount data packets after the data packet of the cyclic check code. When the value is 3, it indicates that the cyclic check code is a 32-bit check code, and a range of a data packet protected by the cyclic check code is protectedPacketsCount data packets after the data packet of the cyclic check code.

The CRC16Value is used for representing a 16-bit check code; and a binary value used for representing the CRC16Value may occupy 16 bits.

The CRC32Value is used for representing a 32-bit check code; and a binary value used for representing the CRC32Value may occupy 32 bits.

The protectedPacketsCount is used for a quantity of data packets protected by a cyclic check code; and a binary value used for representing the protectedPacketsCount may occupy 8 bits.

Still referring to FIG. 5, in S520, a decapsulation device decodes a binary bit stream corresponding to the foregoing target haptic information, to obtain an interchange format of the target haptic information. For example, the binary bit stream is decoded by the processing circuitry into a piece of text-based interchange format data indicating haptic information of the haptic experience dataset. In some examples, one or more haptic devices are driven based on the piece of text-based interchange format data.

A data interchange format refers to a standardized format used when data is interchanged between different systems. In one or more embodiments of this disclosure, the interchange format of the target haptic information is a standardized format used for interchanging data between a server side (namely, an encapsulation device side) and a terminal (namely, a decapsulation device side) (such as an interaction device) that presents haptic information. In at least one aspect, the terminal (such as an interaction device) may obtain the interchange format of the target haptic information by decoding the bit stream, and further, may render and present the target haptic information based on the interchange format of the target haptic information. For example, if the target haptic information is information about vibration, the terminal may present a corresponding vibration effect on the terminal based on the interchange format of the target information. The interchange format of the haptic information is not limited to JSON, and may also be another type of a data interchange format, for example, a data interchange format, such as extensible markup language (XML) or comma-separated values (CSV).

In one or more embodiments of this disclosure, based on the haptic information representation data structure 400 in the AVS shown in FIG. 4 and the field extension of the haptic media bit stream provided in one or more embodiments of this disclosure (for example, the embodiments provided in Table 7 to Table 10.2 above), the decapsulation device can decode the binary bit stream corresponding to the target haptic information to obtain the interchange format of the target haptic information.

Further, the decapsulation device (for example, a terminal client) may render the interchange format of the target haptic information, and perform haptic presentation.

In the solution provided in one or more embodiments shown in FIG. 5, the decapsulation device decodes the binary bit stream corresponding to the target haptic information, to obtain the interchange format of the target haptic information. The binary bit stream is obtained based on the solution of encoding an interchange format of haptic information into a binary bit stream according to the embodiments of this disclosure. In at least one aspect, data is organized and divided in the binary bit stream in a form of a data unit and a data packet, and one data unit includes one or more data packets. The solution provided in embodiments of this disclosure facilitates saving of space occupied by haptic media content, and can reduce bandwidth usage during transmission of the haptic media content. In addition, random access of a haptic signal during transmission is also supported.

The embodiment corresponding to FIG. 5 describes a solution of decoding a bit stream corresponding to target haptic information in detail. An embodiment in which an interchange format of target haptic information is decoded to obtain a bit stream corresponding to the haptic information according to this disclosure is described in detail below through FIG. 7.

FIG. 7 is a schematic flowchart of a method P700 for processing haptic information according to an embodiment of this disclosure. The method P700 is performed by an electronic device, such as the server 210 in FIG. 2 or performed by a processor, that can encode an interchange format of the target haptic information to obtain a haptic media bit stream. Referring to FIG. 7, the method P700 includes S710 and S720.

In S710, the interchange format of the target haptic information is encoded, to obtain the binary bit stream corresponding to the target haptic information, the bit stream includes one or more data units regarding the target haptic information, and the data unit includes one or more data packets. For example, a piece of text-based interchange format data indicating haptic information is obtained. In some examples, the piece of text-based interchange format data is encoded by processing circuitry into a bit stream corresponding to a haptic experience dataset incorporating the haptic information, the binary bit stream including one or more data units, and each one of the one or more data units including one or more data packets and a syntax structure that includes (i) a data unit type indicator indicating a type of the data unit and (ii) a unit-level timestamp indicating an offset time of the data unit from a start time of the haptic experience dataset.

In one or more embodiments of this disclosure, based on the haptic information representation data structure 400 in the AVS shown in FIG. 4, several descriptive fields are added, including field extension of a haptic media bit stream, to support the method operations in one or more embodiments of this disclosure.

A data interchange format refers to a standardized format used when data is interchanged between different systems. In one or more embodiments of this disclosure, the interchange format of the target haptic information is a standardized format used for interchanging data between a server side (namely, an encapsulation device side) and a terminal (namely, a decapsulation device side) (such as an interaction device) that presents haptic information. In at least one aspect, for ease of transmission, the server side decodes the interchange format of the target haptic information into a binary bit stream, and transmits the binary bit stream to the terminal (such as the interaction device). Therefore, after obtaining the interchange format of the target haptic information, the terminal (such as the interaction device) may perform rendering and presentation based on the target haptic information. For example, if the target haptic information is information about vibration, the terminal may present a corresponding vibration effect on the terminal based on the interchange format of the target information. The interchange format of the haptic information is not limited to JSON, and may also be another type of a data interchange format, for example, a data interchange format, such as extensible markup language (XML) or comma-separated values (CSV).

The binary bit stream obtained through encoding and compressing via a haptic media interchange format is a self-contained transmission stream format including a series of data units (AHAS Unit), and each data unit (AHAS Unit) corresponds to a presentation time of the haptic media.

For example, FIG. 6 is a schematic diagram of a relationship between a data unit and a data packet according to an embodiment of this disclosure. Referring to FIG. 6, a binary bit stream includes: an (i−1)^{th} data unit (AHAS Unit (i−1)), an i^{th} data unit (AHAS Unit (i)), an (i+1)^{th} data unit (AHAS Unit (i+1)), and the like. Each data unit includes at least one data packet. As shown in FIG. 6, the i^{th} data unit (AHAS Unit (i)) includes a data unit header (AHAS Unit Header), a data packet 0 (AHAS Packet 0), a data packet 1 (AHAS Packet 1), a data packet 2 (AHAS Packet 2), . . . , and a data packet n (AHAS Packet n). Each data packet includes a haptic signal, or metadata or auxiliary information of the haptic signal. Specific details are described in detail in the following embodiments.

From FIG. 6, data is organized and divided in a bit stream in forms of a data unit and a data packet in one or more embodiments of this disclosure. In addition, the data unit and the data packet are divided into different types, and the types of the data unit and the data packet determine a type of data they contain. Table 7 shows types of data units and types of data packets that the data units contain according to an embodiment of this disclosure.

From Table 7, a data unit is classified into at least one of the following types:

### 1. Data Unit of the Initialization Type:

The data unit of the initialization type includes one data packet of the first type, one or more data packets of the second type, one or more data packets of the third type, zero or one or more data packets of the fourth type, and zero or one data packet of the fifth type. Data unit of a time domain/spatial domain type:

### 2. Data Unit of the Time Domain Type or the Spatial Domain Type:

The data unit of the time domain type or the spatial domain type includes one or more data packets of the seventh type, and zero or one data packet of the fifth type.

### 3. Data Unit of the Silent Type:

The data unit of the silent type includes a data packet of the sixth type.

After the relationship between the data unit and the data packet, the types of the data unit and the types of the data packet in one or more embodiments of this disclosure are introduced, syntax structures of the bit stream, the data unit, and the data packet are introduced below through Table 8 to Table 10, respectively. In an embodiment of this disclosure, a syntax and semantics of the bit stream are shown in Table 8.

In an embodiment of this disclosure, a syntax and semantics of a data unit (AHAS Unit) are shown in Table 11. The quantity of bits shown in Table 11 is example data, or may be another value, which is not limited in this disclosure.

TABLE 11

| Syntax | Quantity of bits | Mnemonic |
|---|---|---|
| avsHapticUnit( ) | | |
| { | | |
| AHASUnitType; | 3 | uimsbf |
| AHASUnitDependency; | 1 | bool |
| AHASUnitLayerFlag | 1 | bool |
| if(AHASUnitLayerFlag){ | | |
| AHASLayer} | 3 | uimsbf |
| else{ | | |
| reserved} | 3 | uimsbf |
| AHASUnitTimestamp; | 32 | uimsbf |
| AHASUnitLength; | 32 | uimsbf |
| while (endOfUnit( ) != 1) { | | |
| avsHapticPacket( ); | | |
| } | | |
| } | | |

Referring to Table 11, the AHASUnitType represents a type of a data unit. In one or more embodiments of this disclosure, a different type of a data unit corresponds to a different binary value. Referring to Table 11, a quantity of bits occupied by the type of the data unit is 3. For example, the type of the data unit that is the silent type may be represented as “100”. For example, a meaning of the binary value of the field may be shown in Table 11.1.

TABLE 11.1

| AHASUnitType | Binary | |
|---|---|---|
| (a type of a data unit) | value | Note |
| UNITTYPE_INIT | 0 | Initialization type |
| UNITTYPE_TEMPORAL | 1 | Time domain type |
| UNITTYPE_SPATIAL | 2 | Spatial domain type |
| UNITTYPE_SILENT | 3 | Silent type |
| Reserved | 4 to 7 | |

Referring to Table 11, AHASUnitDependency represents an encoding dependency indicator.

If a value of the field is a first target value, it indicates that a current data unit does not depend on another data unit of the same type during encoding. If the value of the field is not the first target value, it indicates that the current data unit depends on another data unit of the same type during encoding.

In some embodiments, the first target value may be “0”, a value that is not the first target value may be “1”. Because the data unit of the initialization type and the data unit of the silent type do not depend on another data unit of the same type during encoding, values of the fields in the data unit of the initialization type and the data unit of the silent type are 0.

If a data unit of a time domain or spatial domain type follows the data unit of the initialization type and a value of an AHASUnitDependency field of the data unit of the time domain or spatial domain type is the first target value (such as, 0), it may be considered that the data unit of the initialization type may be used as an encoding initiation unit, namely, a unit from which encoding of a bit stream may be directly started, also namely, a random access point for encoding the bit stream. In an embodiment, a current bit stream may be encoded directly starting from the data unit of the initialization type. The first target value is not limited in this disclosure.

Referring to Table 11, the AHASUnitLayerFlag represents a level indicator.

The level indicator is represented through a binary value. When a value of the field is a second target value, it indicates that a level of a data unit is not indicated. When the value of the field is not the second target value, it indicates that the level of the data unit is indicated. In an embodiment, the second target value may be “0”, and a value that is not the second target value may be “1”. Therefore, when the value of the level indicator AHASUnitLayerFlag is 0, it indicates that the level of the data unit is not indicated. When the value of the field is 1, it indicates that the level of the data unit is indicated. Certainly, the second target value is not limited in this disclosure.

Referring to Table 11, the AHASLayer represents a level identifier of a data unit.

In one or more embodiments of this disclosure, the level identifier is also represented through a binary value. In addition, a priority of the data unit may be determined through a value of the level identifier.

In some embodiments, a smaller value of the field represents a higher priority of the data unit. Otherwise, a larger value of the field represents a lower priority of the data unit. In some other embodiments, alternatively, the larger value of the AHASLayer field represents the higher priority of the data unit. Otherwise, the smaller value of the field represents the lower priority of the data unit. This is not limited in this disclosure.

Referring to Table 11, the AHASUnitTimestamp represents a first offset timestamp. A different timestamp corresponds to a different binary value. In one or more embodiments shown in Table 11, the first offset timestamp may occupy 32 bits.

The first offset timestamp represents an offset time of a data unit relative to a start time of haptic experience, which is in units of clocks. A quantity of clocks included in a second is specified by a timescale field in experience metadata. For example, a ratio of the first offset timestamp AHASUnitTimestamp to the timescale is a quantity of elapsed seconds of haptic experience.

For data units of different types, a value of the field may follow the following constraint:
for a data unit of an initialization type, the field has no practical meaning;
for a data unit of a silent type, the field is to be greater than a timestamp of any data packet in a data unit of a time domain/spatial domain type preceding the data unit of the silent type.
for a data unit of a time domain type or a spatial domain type, a timestamp of any data packet included in an i^{th} data unit is to be less than a timestamp of any data packet included in an (i+1)^{th} data unit. In some embodiments, the field is to be a minimum value of timestamps of M data packets included in the field. In some other embodiments, the field is to be a maximum value of the timestamps of the M data packets included in the field.

The first offset timestamp may be configured for implementing random access of a haptic signal during transmission. Specific implementations are described in detail in subsequent embodiments about a second offset timestamp.

Referring to Table 11, the AHASUnitLength represents a quantity of bytes of all data packets in a data unit. A different quantity of bytes corresponds to a different binary value. In one or more embodiments shown in Table 9, a quantity of bytes of all the data packets in the data unit may occupy 32 bits.

Referring to Table 11, the endOfUnit ( ) is a function for determining whether a data packet in a data unit ends, and if the data packet in the data unit ends, the function returns 1; and if the data unit does not end, the function returns 0. For example, after AHASUnitLength bytes of data packet data included in a data packet is parsed, a data unit ends.

A syntax and semantics of a data unit (AHAS Packet) are introduced through Table 12. A quantity of bits shown in Table 12 is provided as a non-limiting example.

TABLE 12

| Syntax | Quantity of bits | Mnemonic |
|---|---|---|
| avsHapticPacket( ) | | |
| { | | |
| AHASPacketType; | 4 | uimsbf |
| AHASPacketLength; | 20 | uimsbf |
| if(AHASPacketType==6){ | | |
| AHASPacketTimestamp;} | 24 | uimsbf |
| AHASPacketPayload(AHASPacketType); | | |
| byteAlignment( ) | | |
| } | | |

Referring to Table 12, the AHASPacketType represents a type of a data packet. In one or more embodiments of this disclosure, different types of data packets correspond to different binary values. Referring to Table 12, a quantity of bits occupied by the type of the data packet is 4. For example, the type of the data packet is a sixth type including silent information, and may be represented as “0110”. For example, a meaning of a binary value of the field may be shown in Table 10.1. Details are not described herein again.

Referring to Table 12, the AHASPacketLength is used for indicating a quantity of bytes of a payload of a data packet, namely, a quantity of bytes of the AHASPacketPayload. In one or more embodiments of this disclosure, a quantity of bytes of the payload of the data packet may be represented through a binary value. Referring to Table 12, a quantity of bits occupied by the quantity of bytes of the payload of the data packet is 20.

Referring to Table 12, the AHASPacketTimestamp represents a second offset timestamp. A different timestamp corresponds to a different binary value. In one or more embodiments shown in Table 12, the second offset timestamp may occupy 24 bits.

The second offset timestamp is used for representing an offset, in units of clocks, relative to a first timestamp of a data unit where the data packet is located. A quantity of clocks included in a second is specified by a timescale field in experience metadata. In at least one aspect, in some embodiments, the second offset timestamp AHASPacketTimestamp represents a minimum value of timestamps of all haptic events included in the data packet. In some other embodiments, the second offset timestamp AHASPacketTimestamp represents a maximum value in the timestamps of all the haptic events included in the data packet.

In one or more embodiments of this disclosure, a timestamp of a current haptic signal data packet may be determined based on the second offset timestamp of the data packet and the first offset timestamp of the data unit where the data packet is located.

In a case that the first offset timestamp AHASUnitTimestamp represents a minimum value of timestamps of all data packets included in the first offset timestamp, AHASUnitTimestamp+AHASPacketTimestamp may be determined as the timestamp of the current haptic signal data packet. In a case that the first offset timestamp AHASUnitTimestamp represents a maximum value of the timestamps of all the data packets included in the first offset timestamp, AHASUnitTimestamp−AHASPacketTimestamp may be determined as the timestamp of the current haptic signal data packet.

According to the solution provided in one or more embodiments of this disclosure, the timestamp of the current haptic signal data packet may be determined through the second offset timestamp of the current data packet and the first offset timestamp of the data unit where the data packet is located, thereby supporting random access of a haptic signal during transmission.

Referring to Table 12, the byteAlignment( ) is a function for determining byte alignment. If data included in a current data packet is an integer quantity of bytes, it returns 0; and if the data included in the current data packet is not an integral quantity of bytes, it returns 0 after the last byte is supplemented.

Referring to Table 12, a syntax of the AHASPacketPayload may be introduced with reference to Table 12.2 provided above.

TABLE 12.2

| | | |
|---|---|---|
| | Quantity | |
| Syntax | of bits | Mnemonic |

```
avsPacketPayload(AHASPacketType)
{
  switch (AHASPacketType) {
  case PACTYPE_METADATAEXPERIENCE:
  readMetadataExperience( );
  break;
  case PACTYPE_METADATAPATTERN:
  readMetadataPattern( );
  break;
  case PACTYPE_METADATACHANNEL:
  readMetadataChannel( );
  break;
  case PACTYPE_DATA:
  readData ( );
  break;
  case PACTYPE_LIBRARYEFFECTS:
  readLibrary( );
  break;
  case PACTYPE_SILENTINFO:
  readSilentInfo( );
  break;
  case PACTYPE_CRC:
  readCRC( );
  break;
  }
}
```

According to different types of data packets, in a process of executing the syntax in Table 12.2, a syntax of a payload of a data packet of a corresponding type shown in one of Table 12.2-A to Table 12.2-G is executed. Quantities of bits shown in Table 12.2-A to Table 12.2-G are provided as non-limiting examples.

In a case that a type of a data packet is a first type including haptic experience metadata, in a process of executing the syntax in Table 12.2, a syntax of a payload of a data packet shown in Table 12.2-A is executed.

TABLE 12.2-A

| Syntax | Quantity of bits | Mnemonic |
|---|---|---|
| readMetadataExperience( ) | | |
| { | | |
| version; | 8 | uimsbf |
| dateLength; | 8 | uimsbf |
| date; | dateLength*8 | string |
| descriptionLength; | 8 | uimsbf |
| description; | descriptionLength*8 | string |
| timescale | 16 | uimsbf |
| patternCount; | 8 | uimsbf |
| deviceCount; | 8 | uimsbf |
| for (i = 0; i < deviceCount; i++) { | | |
| readDevice( ); | | |
| } | | |
| } | | |

In a case that the type of the data packet is the first type including the haptic experience metadata, a payload of the data packet includes one or more of the following fields shown in Table 12.2-A. Each field in Table 12.2-A may be represented through a binary value. In at least one aspect, specific indication information of each field is as follows:

The Version is used for indicating information on a standard version followed by haptic experience; and a binary value used for representing the Version may occupy 8 bits.

The dateLength is used for indicating a string length of a creation date of haptic experience; and a binary value configured for representing the dateLength may occupy 8 bits.

The Date is used for indicating a creation date of haptic experience; and a binary value configured for representing the Date may occupy dateLength×8 bits.

The descriptionLength is used for indicating a string length of a haptic experience description; and a binary value used for representing the descriptionLength may occupy 8 bits.

The Description is used for indicating a haptic experience description; and a binary value used for representing the Description may occupy descriptionLength×8 bits.

The Timescale is used for indicating a time scale of a haptic experience, and a value of the field represents a quantity of clock units included in a second; and a binary value used for representing the Timescale may occupy 16 bits.

The patternCount is used for indicating a quantity of patterns included in haptic experience; and a binary value used for representing the patternCount may occupy 8 bits.

The deviceCount is used for indicating a quantity of devices corresponding to haptic experience; and a binary value used for representing the deviceCount may occupy 8 bits.

For a syntax of the readDeviceo in Table 12.2-A, reference may be made to Table 12.2-A1.

TABLE 12.2-A1

| Syntax | Quantity of bits | Mnemonic |
|---|---|---|
| readDevice( ) | | |
| { | | |
| deviceId; | 8 | uimsbf |
| nameLength | 8 | uimsbf |
| deviceName; | nameLength *8 | string |
| bodyPartFlag | 1 | bool |
| If(bodyPartFlag == 1){ | | |
| bodyParts;} | 8 | uimsbf |
| } | | |

The payload of the foregoing data packet further includes: one or more of the following fields shown in Table 12.2-A1 about a j^{th} device. Each field in Table 12.2-A1 may be represented through a binary value. In at least one aspect, specific indication information of each field is as follows:

The deviceId is used for indicating an identifier of the j^{th} device; and a binary value used for representing the deviceId may occupy 8 bits.

The nameLength is used for indicating a string length of a name of the jth device; and a binary value used for representing the nameLength may occupy 8 bits.

The deviceName is used for indicating the name of the j^{th} device readable by human; and a binary value used for representing the deviceName may occupy 8 bits.

The bodyPartFlag is used for indicator of whether the device corresponds to a body part; and a binary value used for representing the bodyPartFlag may occupy 1 bit. For example, the value that is 1 indicates information on a body part corresponding to the device. The value that is 0 does not indicate information on the body part corresponding to the device.

The bodyParts is used for indicating a body part corresponding to the device; and a binary value used for representing the bodyParts may occupy 8 bits.

In a case that the type of the data packet is the second type including the haptic pattern metadata, in a process of executing the syntax in Table 12.2, a syntax of the payload of the data packet shown in Table 12.2-B3 is executed.

TABLE 12.2-B

| | Quantity | |
|---|---|---|
| Syntax | of bits | Mnemonic |
| readMetadataPattern( ) | | |
| { | | |
| id; | 8 | uimsbf |
| patternType; | 8 | uimsbf |
| semanticisFlag | 1 | boolean |
| if(semanticisFlag){ | | |
| sementicsType} | 8 | uimsbf |
| referenceDeviceCount; | 8 | uimsbf |
| for (i = 0; i < referenceDeviceCount; i++) { | | |
| referenceDeviceId; | 8 | uimsbf |
| } | | |
| channelCount; | 16 | uimsbf |
| } | | |

In a case that the type of the data packet is the second type including the haptic pattern metadata, the payload of the data packet includes one or more of the following fields shown in Table 12.2-B3. Each field in Table 12.2-B3 may be represented through a binary value. In at least one aspect, specific indication information of each field is as follows:

The Id is used for indicating an identifier of a haptic pattern; and a binary value used for representing the Id may occupy 8 bits.

The patternType is used for indicating a type of the haptic pattern; and a binary value configured for representing the patternType may occupy 8 bits. For example, a type of a data pattern is an acceleration, which may be represented as “0000 0010”. For example, a meaning of the binary value of the field may be shown in Table 12.2-B31.

TABLE 12.2-B1

| Value of patternType | Meaning |
|---|---|
| 0 | Vibration tactility |
| 1 | Pressure |
| 2 | Acceleration |
| 3 | Speed |
| 4 | Temperature |
| 5 | Electro tactility |
| 6 to 255 | Reserved |

The semanticisFlag is an indicator of whether semantics exists for a haptic event corresponding to the haptic pattern; and a binary value used for representing the semanticisFlag may occupy 1 bit. For example, when the value is 1, it indicates that the haptic event corresponding to the haptic pattern has semantics. When the value is 0, it indicates that the haptic event corresponding to the haptic pattern do not has semantics.

The sementicsType is used for representing an indicator of a specification followed by semantics of a haptic event; and a binary value used for representing the sementicsType may occupy 8 bits. For example, when the value is 0, it indicates that the semantics of the haptic event follows a specification defined by this standard. When the value is 1, it indicates that the semantics of the haptic event follows a specification of an external standard. When the value is 2, it indicates that the semantics of the haptic event is user-defined.

The referenceDeviceCount is used for representing a quantity of devices corresponding to a haptic pattern; and a binary value configured for representing the referenceDeviceCount may occupy 8 bits.

The referenceDeviceId is used for indicating an identifier of a device corresponding to a haptic pattern; and a binary value used for representing the referenceDeviceId may occupy 8 bits.

The channelCount is used for indicating a quantity of haptic channels included in a haptic pattern; and a binary value used for representing the channelCount may occupy 16 bits.

In a case that the type of the data packet is the third type including the haptic channel metadata, in a process of executing the syntax in Table 12.2, a syntax of the payload of the data packet shown in Table 12.2-C is executed.

TABLE 12.2-C

| Syntax | Quantity of bits | Mnemonic |
|---|---|---|
| readMetadataChannel( ) | | |
| { | | |
| id; | 16 | uimsbf |
| perceptionId; | 8 | uimsbf |
| descriptionLength; | 8 | uimsbf |
| description; | descriptionLength*8 | string |
| gain; | 32 | imsbf |
| referenceDeviceCount; | 8 | uimsbf |
| for (i = 0; i < referenceDeviceCount; | | |
| i++) { | | |
| referenceDeviceId; | 8 | uimsbf |
| { | | |
| eventsCount; | 16 | uimsbf |
| } | | |

In a case that the type of the data packet is the third type including the haptic channel metadata, the payload of the data packet includes one or more of the following fields shown in Table 12.2-C. Each field in Table 12.2-C may be represented through a binary value. In at least one aspect, specific indication information of each field is as follows:

The Id is used for indicating an identifier of a haptic channel; and a binary value used for representing the Id may occupy 16 bits.

The perceptionId is used for indicating an identifier of a haptic pattern corresponding to a haptic channel; and a binary value configured for representing the perceptionId may occupy 8 bits.

The descriptionLength is used for indicating a string length of a haptic channel description; and a binary value configured for representing the descriptionLength may occupy 8 bits.

The Description is configured for indicating the haptic channel description; and a binary value configured for representing the Description may occupy 8×descriptionLength bits.

The Gain is used for indicating a gain of a haptic channel; and a binary value used for representing the Gain may occupy 32 bits. In at least one aspect, 2-31 is used as a unit. The Gain is applied to all events included in a current channel, and is used for restoring a normalized signal value to an original signal value.

The referenceDeviceCount is used for indicating a quantity of devices corresponding to a haptic channel; and a binary value configured for representing the referenceDeviceCount may occupy 8 bits.

The referenceDeviceId is configured for indicating an identifier of a device corresponding to a haptic channel; and a binary value configured for representing the referenceDeviceId may occupy 8 bits.

The eventsCount is used for indicating a quantity of haptic events included in a haptic channel; and a binary value configured for representing the eventsCount may occupy 16 bits.

In a case that the type of the data packet is the seventh type including the haptic signal, in a process of executing the syntax in Table 12.2, a syntax of the payload of the data packet shown in Table 12.2-D is executed.

TABLE 12.2-D

| | Quantity | |
|---|---|---|
| Syntax | of bits | Mnemonic |
| readData( ) { | | |
| packetDependency; | 1 | bool |
| perceptionId; | 8 | uimsbf |
| channelId; | 8 | uimsbf |
| eventsCount; | 16 | uimsbf |
| for (i = 0; i < eventsCount; i++) { | | |
| readEvent( ); | | |
| } | | |
| } | | |

In a case that the type of the data packet is the seventh type including the haptic signal, the payload of the data packet includes one or more of the following fields shown in Table 12.2-D. Each field in Table 12.2-D may be represented through a binary value. In at least one aspect, specific indication information of each field is as follows:

The packetDependency represents an indicator of whether a current data packet depends on another data packet of the same type during encoding; and a binary value used for representing the packetDependency may occupy 1 bit. For example, when a value of the field is 0, it indicates that the current data packet does not depend on another data packet of the same type during encoding. When a value of the field is 1, it indicates that the current data packet depends on another data packet of the same type during encoding.

The perceptionId is used for indicating an identifier of a haptic pattern corresponding to a corresponding haptic event in a data packet; and a binary value used for representing the perceptionId may occupy 8 bits.

The channelId is used for indicating an identifier of a haptic channel corresponding to a corresponding haptic event in a data packet; and a binary value configured for representing the channelId may occupy 8 bits.

The eventsCount is used for indicating a quantity of haptic events corresponding to a data packet; and a binary value configured for representing the eventsCount may occupy 16 bits.

For a syntax of readEvent( ) in Table 12.2-D, reference may be made to Table 12.2-D1.

TABLE 12.2-D1

| Syntax | Quantity of bits | Mnemonic |
|---|---|---|
| readEvent( ) { | | |
| eventId | 16 | uimsbf |
| eventType; | 4 | uimsbf |
| eventSementicsFlag | 1 | bool |
| if (eventSementicsFlag) { | | |
| semanticKeywords | 12 | uimsbf |
| } | | |
| if (eventType == 2) { | | |
| referEventId; | 16 | uimsbf |
| } | | |
| relativePosition | 32 | imsbf |
| if (eventType == 1) { | | |
| duration; | 32 | uimsbf |
| } | | |
| amplitude | 8 | uimsbf |
| baseFrequency | 16 | uimsbf |
| numComponents | 16 | uimsbf |
| for (i = 0; i < numComponents; i++) { | | |
| readEventComponent( ); | | |
| } | | |
| } | | |

The payload of the foregoing data packet further includes: one or more of the following fields about an m^{th} haptic event shown in Table 12.2-D1. Each field in Table 12.2-D1 may be represented through a binary value. In at least one aspect, specific indication information of each field is as follows:

The eventId is used for indicating an identifier of a haptic event; and a binary value used for representing the eventId may occupy 16 bits.

The eventType is used for indicating a type of a haptic event; and a binary value used for representing the eventType may occupy 4 bits. For example, when a value of the field is 0, it indicates that the event is an instantaneous event, when the value of the field is 1, it indicates that the event is a sustained event, and when the value of the field is 2, it indicates that the event is a reference event.

The eventSementicsFlag is used for representing a value of an indicator indicating whether semantics of the haptic event is indicated; and a binary value used for representing the eventSementicsFlag may occupy 1 bit. For example, when the value is 0, semantics of a haptic event is not indicated. When the value is 1, semantics of a haptic event is indicated.

The semanticKeywords represents semantic information of a haptic event; and a binary value used for representing the semanticKeywords may occupy 12 bits. The semantics of the haptic event is an event auxiliary information keyword that describes an intention of a content producer.

The referEventId is used for indicating a knowledge haptic event identifier corresponding to a reference event; and a binary value used for representing the referEventId may occupy 16 bits.

The relativePosition is used for indicating a time or space offset of a haptic event; and a binary value used for representing the relativePosition may occupy 32 bits.

The Duration is used for indicating a duration of a haptic event, and the attribute exists when an event type is a sustained event; and a binary value used for representing the Duration may occupy 32 bits.

The Amplitude is used for indicating a maximum signal amplitude value of a haptic event; and a binary value used for representing the Amplitude may occupy 8 bits.

The baseFrequency is used for indicating a signal reference frequency of a haptic event; and a binary value used for representing the baseFrequency may occupy 16 bits.

The numComponents is used for indicating a quantity of a haptic event component, and the haptic event component may be a time domain component or a frequency domain component of a haptic event; and a binary value used for representing the numComponents may occupy 16 bits.

For a syntax of readEventComponent( ) in Table 12.2-D1, reference may be made to Table 12.2-D2.

TABLE 12.2-D2

| | Quantity | |
|---|---|---|
| Syntax | of bits | Mnemonic |
| readEventComponent( ) { | | |
| refer_event_id | 16 | uimsbf |
| position_flag | 1 | bool |
| amplitude_flag | | |
| frequency_flag | | |
| if(position_flag == 1){ | | |
| relative_position;} | 16 | uimsbf |
| if(relative_amplitude == 1){ | | |
| relative_amplitude; } | 16 | uimsbf |
| if(relative_frequency == 1){ | | |
| relative_frequency; } | 16 | uimsbf |
| } | | |

The payload of the foregoing data packet further includes: one or more of the following fields about a k^{th} haptic event component shown in Table 12.2-D2. Each field in Table 12.2-D2 may be represented through a binary value. In at least one aspect, specific indication information of each field is as follows:

The refer_event_id is used for indicating an identifier of a haptic event to which a haptic event component belongs; and a binary value used for representing the refer_event_id may occupy 16 bits.

The position flag is used for representing an indicator of whether a haptic event component includes a time-space domain offset; and a binary value used for representing the position flag may occupy 1 bit. For example, when the value of position flag is 1, it indicates that the haptic event component includes the time-space domain offset, and when the value is 0, it indicates that the haptic event component does not include the time-space domain offset.

The amplitude flag is used for representing an indicator of whether a haptic event component includes an amplitude value offset; and a binary value used for representing the amplitude flag may occupy 1 bit. For example, when the value of the amplitude flag is 1, it indicates that the haptic event component includes the amplitude value offset, and when the value is 0, it indicates that the haptic event component does not include the amplitude value offset.

The frequency_flag is used for representing an indicator of whether a haptic event component includes a frequency offset; and a binary value used for representing the frequency_flag may occupy 1 bit. For example, when the value of the frequency_flag is 1, it indicates that the haptic event component includes the frequency offset, and when the value is 0, it indicates that the haptic event component does not include a frequency offset.

The relative_position is used for representing a time or space offset of a haptic event component relative to a haptic event; and a binary value used for representing the relative_position may occupy 16 bits.

The relative_amplitude is used for representing an amplitude value ratio of a haptic event component relative to a haptic event, and is in a value range of 0 to 215 with 2-15 as a unit; and a binary value used for representing the relative_amplitude may occupy 16 bits.

The relative_frequency is used for representing a frequency offset of a haptic event component relative to a haptic event; and a binary value used for representing the relative_frequency may occupy 16 bits.

In a case that the type of the data packet is the fourth type including a knowledge haptic event, in a process of executing the syntax in Table 12.2, a syntax of the payload of the data packet shown in Table 12.2-E is executed.

TABLE 12.2-E

| Syntax | Quantity of bits | Mnemonic |
|---|---|---|
| readLibrary ( ) { | | |
| patternId; | 8 | uimsbf |
| eventsCount; | 16 | uimsbf |
| for (i = 0; i < eventsCount; i++) { | | |
| readLibraryEvent( ); | | |
| } | | |
| } | | |

In a case that the type of the data packet is the fourth type including the knowledge haptic event, the payload of the data packet includes one or more of the following fields shown in Table 12.2-E. Each field in Table 12.2-E may be represented through a binary value. In at least one aspect, specific indication information of each field is as follows:

The patternId is used for representing an identifier of a haptic pattern corresponding to a knowledge haptic event; and a binary value used for representing the patternId may occupy 8 bits.

The eventsCount is used for representing a quantity of knowledge haptic events corresponding to a data packet; and a binary value used for representing the eventsCount may occupy 16 bits.

For a syntax of readLibraryEvent( ) in Table 12.2-E, reference may be made to Table 12.2-E1.

TABLE 12.2-E1

| | Quantity | |
|---|---|---|
| Syntax | of bits | Mnemonic |
| readLibraryEvent( ) { | | |
| eventId | 16 | uimsbf |
| eventType; | 4 | uimsbf |
| eventSementicsFlag | 1 | bool |
| if (eventSementicsFlag) { | | |
| semanticKeywords | 12 | uimsbf |
| } | | |
| relativePosition | 32 | imsbf |
| if (eventType == 1) { | | |
| duration; | 32 | uimsbf |
| } | | |
| amplitude | 8 | uimsbf |
| baseFrequency | 16 | uimsbf |
| numComponents | 16 | uimsbf |
| for (i = 0; i < numComponents; i++) { | | |
| readEventComponent( ); | | |
| } | | |
| } | | |

The payload of the foregoing data packet further includes: one or more of the following fields about an h^{th} knowledge haptic event shown in Table 12.2-E1. Each field in Table 12.2-E1 may be represented through a binary value. In at least one aspect, specific indication information of each field is as follows:

The eventId is used for representing an identifier of a knowledge haptic event; and a binary value used for representing the eventId may occupy 16 bits.

The eventType is used for representing a type of the knowledge haptic event; and a binary value used for representing the eventType may occupy 4 bits. For example, when a value of the field is 0, it indicates that an event is an instantaneous event. When the value of the field is 1, it indicates that the event is a sustained event.

The eventSementicsFlag is an indicator used for representing whether semantics of a knowledge haptic event is indicated; and a binary value used for representing the eventSementicsFlag may occupy 1 bit. For example, when the value is 0, semantics of a knowledge haptic event is not indicated. When the value is 1, the semantics of the knowledge haptic event is indicated.

The semanticKeywords is used for representing semantic information of an event; and a binary value used for representing the semanticKeywords may occupy 12 bits. The semantics of the knowledge haptic event is an event auxiliary information keyword that describes an intention of a content producer.

The relativePosition is used for representing a time or space offset of a knowledge haptic event; and a binary value used for representing the relativePosition may occupy 32 bits.

The Duration is used for representing a duration of a knowledge haptic event, and the attribute exists when an event type is a sustained event; and a binary value used for representing the Duration may occupy 32 bits.

The Amplitude is used for representing a maximum signal amplitude value of a knowledge haptic event; and a binary value used for representing the Amplitude may occupy 8 bits.

The baseFrequency is used for representing a signal reference frequency of a knowledge haptic event; and a binary value used for representing the baseFrequency may occupy 16 bits.

The numComponents is used for representing a quantity of a knowledge haptic event component, and the knowledge haptic event component may be a time domain component or a frequency domain component of a knowledge haptic event; and a binary value used for representing the numComponents may occupy 16 bits.

For a syntax of readEventComponent( ) in Table 12.2-E1, reference may be made to Table 12.2-D2. Details are not described herein again.

In a case that the type of the data packet is the sixth type including the silent data, in a process of executing the syntax in Table 12.2, a syntax of the payload of the data packet shown in Table 12.2-F is executed.

TABLE 12.2-F

| Syntax | Quantity of bits | Mnemonic |
|---|---|---|
| readSilentInfo ( ) { | | |
| silentDuration; | 16 | uimsbf |
| } | | |

In a case that the type of the data packet is the sixth type including the silent data, the payload of the data packet includes a field shown in Table 12.2-F. Afield in Table 12.2-F may be represented through a binary value. In at least one aspect, specific indication information of the field is as follows:

The silentDuration is used for representing a length of a silent time, and is used in a unit of a time scale; and a binary value used for representing the silentDuration may occupy 16 bits.

In a case that the type of the data packet is the fifth type including the cyclic check code, in a process of executing the syntax in Table 12.2, a syntax of the payload of the data packet shown in Table 12.2-G is executed.

TABLE 12.2-G

| Syntax | Quantity of bits | Mnemonic |
|---|---|---|
| readCRC( ) | | |
| { | | |
| CRCType | 8 | uimsbf |
| if (CRCType == 0) { | | |
| CRC16Value; | 16 | uimsbf |
| } else if (CRCType == 1) { | | |
| CRC32Value; | 32 | uimsbf |
| } else if (CRCType == 2) { | | |
| protectedPacketsCount; | 8 | uimsbf |
| CRC16Value; | 16 | uimsbf |
| } else if (CRCType == 3) { | | |
| protectedPacketsCount; | 8 | uimsbf |
| CRC32Value; | 32 | uimsbf |
| } | | |
| } | | |

In a case that the type of the data packet is the fifth type including the cyclic check code, the payload of the data packet includes one or more of the following fields shown in Table 12.2-G. Each field in Table 12.2-G may be represented through a binary value. In at least one aspect, specific indication information of each field is as follows:

The CRCType is used for representing a type of a cyclic check code; and a binary value used for representing the CRCTypey may occupy 8 bits. For example, when the value is 0, it indicates that the cyclic check code is a 16-bit check code, and a data packet protected by the cyclic check code is a data packet after a data packet of the cyclic check code. When the value is 1, it indicates that the cyclic check code is a 32-bit check code, and a data packet protected by the cyclic check code is a data packet after a data packet of the cyclic check code. When the value is 2, it indicates that the cyclic check code is a 16-bit check code, and a range of a data packet protected by the cyclic check code is protectedPacketsCount data packets after the data packet of the cyclic check code. When the value is 3, it indicates that the cyclic check code is a 32-bit check code, and a range of a data packet protected by the cyclic check code is protectedPacketsCount data packets after the data packet of the cyclic check code.

The CRC16Value is used for representing a 16-bit check code; and a binary value used for representing the CRC16Value may occupy 16 bits.

The CRC32Value is used for representing a 32-bit check code; and a binary value used for representing the CRC32Value may occupy 32 bits.

The protectedPacketsCount is used for a quantity of data packets protected by a cyclic check code; and a binary value used for representing the protectedPacketsCount may occupy 8 bits.

Based on the haptic information representation data structure 400 in the AVS shown in FIG. 4 and the field extension of the haptic media bit stream provided in one or more embodiments of this disclosure (for example, the embodiments provided in Table 7, Table 8, Table 11, and Table 12.2 above), the interchange format of the target haptic information can be encoded, to obtain the binary bit stream corresponding to the target haptic information.

Still referring to FIG. 7, in S720, the bit stream is encapsulated to obtain a media file including the haptic information. For example, a media file encapsulating the haptic experience dataset is obtained by the processing circuitry. In some examples, the media file is transmitted to a processing device that is configured to decode the media file into the piece of text-based interchange format data and drive one or more haptic devices based on the piece of text-based interchange format data.

The server side (namely, the encapsulation device) may encapsulate the bit stream, for example, encapsulate the bit stream based on ISOBMFF, to obtain a media file including the haptic information.

In the solution provided in one or more embodiments shown in FIG. 7, the interchange format of the target haptic information is encoded, to obtain a binary bit stream corresponding to the target haptic information. Further, the binary bit stream may be encapsulated to obtain the media file including haptic information. The embodiments of this disclosure provide a solution of encoding the interchange format of the haptic information into the binary bit stream. In at least one aspect, data is organized and divided in a form of a data unit and a data packet in the binary bit stream, and a data unit includes one or more data packets. The solution provided in embodiments of this disclosure facilitates saving of space occupied by haptic media content, and can reduce bandwidth usage during transmission of the haptic media content. In addition, random access of a haptic signal during transmission is also supported.

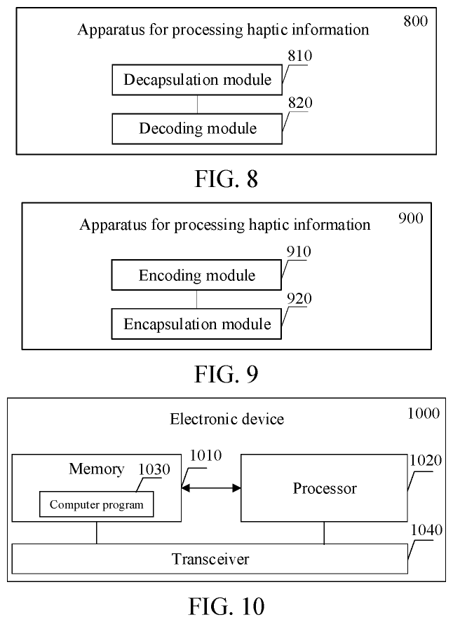

The embodiments of the method for processing haptic information according to this disclosure are described in detail above with reference to FIG. 1 to FIG. 7. The apparatus embodiments of this disclosure are described in detail below with reference to FIG. 8 and FIG. 9.

FIG. 8 is a schematic structural diagram of an apparatus 800 for processing haptic information according to an embodiment of this disclosure. The apparatus 800 for processing haptic information is configured in an electronic device that may decode a haptic media bit stream, for example, a decapsulation device. The decapsulation device may be, for example, the terminal 220 in FIG. 2. As shown in FIG. 8, the apparatus 800 for processing haptic information includes a decapsulation module 810 and a decoding module 820.

The decapsulation module 810 is configured to decapsulate a media file including target haptic information to obtain a binary bit stream corresponding to the target haptic information. The bit stream includes one or more data units related to the target haptic information, and the data units include one or more data packets. The decoding module 820 is configured to decode the binary bit stream corresponding to the target haptic information to obtain an interchange format of the target haptic information. The interchange format of the target haptic information is configured for rendering and presenting the target haptic information.

In some embodiments, based on the solution, a syntax structure of the data unit includes a type of the data unit. A different type corresponds to a different binary value. The type of the data unit includes an initialization type, a silent type, a time domain type, and a spatial domain type.

In some embodiments, based on the solution, in a case that the type of the data unit is the time domain type or the spatial domain type, the syntax structure of the data unit further includes: a first offset timestamp, different timestamps corresponding to different binary values, the first offset timestamp representing a minimum value or a maximum value of timestamps of all data packets included in the data unit, a timestamp of an i^{th} data unit being less than a timestamp of an (i+1)^{th} data unit, and a value of i being a positive integer;

In some embodiments, based on the solution, in a case that the type of the data unit is the silent type, the syntax structure of the data unit further includes the first offset timestamp, different timestamps corresponding to different binary values, the first offset timestamp being greater than a maximum value of timestamps of all data packets included in a target data unit, the target data unit being the data unit of the time domain type or the data unit of the spatial domain type preceding the data unit of the silent type;

In some embodiments, based on the solution, the syntax structure of the data unit further includes a decoding dependency indicator. A different decoding dependency indicator corresponds to a different binary value. In a case that the decoding dependency indicator of a current data unit is a first target value, the current data unit does not depend on another data unit of the same type during decoding. In a case that the decoding dependency indicator of the current data unit is not the first target value, the current data unit depends on another data unit of the same type during decoding.

In some embodiments, based on the solution, if the decoding dependency indicator included in a next data unit of the time domain type or the spatial domain type of the data unit of the initialization type is the first target value, the data unit of the initialization type is a decoding initialization unit.

In some embodiments, based on the solution, the syntax structure of the data unit further includes a level indicator and a level identifier, different level indicators corresponding to different binary values, different level identifiers corresponding to different binary values, and a priority of the data unit being determined through a value of the level identifier if the level indicator is a second target value.

In some embodiments, based on the solution, the syntax structure of the data packet includes a type of the data packet, and different types correspond to different binary values.

The type of the data packet includes:
a first type including haptic experience metadata;
a second type including haptic pattern metadata;
a third type including haptic channel metadata;
a fourth type including a knowledge haptic event;
a fifth type including a cyclic check code,
a sixth type including silent information, and
a seventh type including a haptic signal.

In some embodiments, based on the solution, in a case that the type of the data packet is the seventh type, the syntax structure of the data packet further includes a second offset timestamp, and different timestamps correspond to different binary values. The second offset timestamp represents an offset relative to a first timestamp of a data unit where the data packet is located. The second offset timestamp represents a minimum value or a maximum value of timestamps of all haptic events included in the data packet.

In some embodiments, based on the solution, the syntax structure of the data packet further includes a quantity of bytes of a payload, and different quantities of bytes correspond to different binary values.

If the type of the data packet is the first type, the payload of the data packet includes one or more pieces of the following information that are represented through the binary value: a standard version followed by a haptic experience, a string length of a creation date of the haptic experience, the creation date of the haptic experience, a string length of a haptic experience description, the haptic experience description, a time scale of the haptic experience, a quantity of patterns included in the haptic experience, and a quantity of devices corresponding to the haptic experience; and if the type of the data packet is the first type, the payload of the data packet further includes one or more pieces of the following information about a j^{th} device: a device identifier, a string length of a name of the device, a human-readable device name, and an indicator of whether the device corresponds to a body part, a value of j being a positive integer not greater than a quantity of devices corresponding to the haptic experience.

If the type of the data packet is the second type, the payload of the data packet includes one or more pieces of the following information that are represented through the binary value: an identifier of a haptic pattern, a type of the haptic pattern, an indicator of whether semantics exists for a haptic event corresponding to the haptic pattern, an indicator of a specification followed by the semantics of the haptic event, a quantity of devices corresponding to the haptic pattern, a device identifier corresponding to the haptic pattern, and a quantity of haptic channels included in the haptic pattern.

If the type of the data packet is the third type, the payload of the data packet includes one or more pieces of the following information that are represented through the binary value: an identifier of a haptic channel, a haptic pattern identifier corresponding to the haptic channel, a string length of a haptic channel description, the haptic channel description, a gain of the haptic channel, a quantity of devices corresponding to the haptic channel, a device identifier of each device corresponding to the haptic channel, and a quantity of haptic events included in the haptic channel.

If the type of the data packet is the seventh type, the payload of the data packet includes one or more pieces of the following information that are represented through the binary value: an indicator of whether a current data packet depends on another data packet of the same type during decoding, an identifier of a haptic pattern corresponding to a corresponding haptic event in the current data packet, an identifier of a haptic channel corresponding to a haptic event in the current data packet, and a quantity of the haptic events in the data packet; if the type of the data packet is the seventh type, the payload of the data packet further includes one or more pieces of the following information about an m^{th} haptic event: a haptic event identifier, a type of a haptic event, an indicator indicating whether semantics of the haptic event is indicated, semantic information of the haptic event, a knowledge haptic event identifier corresponding to a reference event, a time or space offset of the haptic event, a duration of the haptic event, a maximum signal amplitude value of the haptic event, a signal reference frequency of the haptic event, and a quantity of haptic event components, a value of m being a positive integer not greater than a quantity of the haptic events in the data packet; and if the type of the data packet is the seventh type, the payload of the data packet further includes one or more pieces of the following information about a k^{th} haptic event component: an identifier of a haptic event to which the haptic event component belongs, an indicator of whether the haptic event component includes a time-space domain offset, an indicator of whether the haptic event component includes an amplitude value offset, an indicator of whether the haptic event component includes a frequency offset, a time or space offset of the haptic event component relative to the haptic event, and an amplitude value ratio of the haptic event component relative to the haptic event, a value of k being a positive integer not greater than the quantity of the haptic event components in the haptic event. If the type of the data packet is the fourth type, the payload of the data packet includes one or more pieces of the following information that are represented through the binary value: an identifier of a haptic pattern corresponding to a knowledge haptic event, and a quantity of knowledge haptic events corresponding to the data packet; if the type of the data packet is the fourth type, the payload of the data packet further includes one or more pieces of the following information about an h^{th} knowledge haptic event: an identifier of the knowledge haptic event, a type of the knowledge haptic event, an indicator of whether to indicate semantics of the knowledge haptic event, semantic information of the knowledge haptic event, a time or space offset of the knowledge haptic event, a duration of the knowledge haptic event, a maximum signal amplitude value of the knowledge haptic event, a signal reference frequency of the knowledge haptic event, and a quantity of haptic event components, a value of h being a positive integer not greater than a quantity of the knowledge haptic events; and if the type of the data packet is the fourth type, the payload of the data packet further includes one or more pieces of the following information about a k^{th} haptic event component: an identifier of a knowledge haptic event to which the haptic event component belongs, an indicator of whether the haptic event component includes a time-space domain offset, an indicator of whether the haptic event component includes an amplitude value offset, an indicator of whether the haptic event component includes a frequency offset, a time or space offset of the haptic event component relative to the knowledge haptic event, and an amplitude value ratio of the haptic event component relative to the knowledge haptic event, a value of k being a positive integer not greater than the quantity of the haptic event components in the knowledge haptic event.

If the type of the data packet is the sixth type, the payload of the data packet includes the following information represented through a binary value: the length of the silent time.

If the type of the data packet is the fifth type, the payload of the data packet includes one or more pieces of the following information represented through the binary value: a type of the cyclic check code, different types of cyclic check codes, and a quantity of data packets protected by the cyclic check code.

The apparatus embodiment and the embodiment of the method for processing haptic information may correspond to each other. For similar descriptions, reference may be made to the method embodiment. To avoid repetition, details are not described herein again. In at least one aspect, the apparatus for processing haptic information shown in FIG. 8 may perform the embodiment of the method for processing haptic information shown in FIG. 5, and the foregoing and other operations and/or functions of various modules in the apparatus for processing haptic information are separately configured for implementing the embodiment of the method for processing haptic information shown in FIG. 5. For brevity, details are not described herein again.

FIG. 9 is a schematic structural diagram of an apparatus 900 for processing haptic information according to an embodiment of this disclosure. The apparatus 900 for processing haptic information is configured in an electronic device, such as the server 210 in FIG. 2, that may encode an interchange format to obtain a haptic media bit stream. As shown in FIG. 9, the apparatus 900 for processing haptic information includes an encoding module 910 and an encapsulation module 920.

The encoding module 910 is configured to encode an interchange format of a target haptic information, to obtain a binary bit stream corresponding to the target haptic information. The bit stream includes one or more data units regarding the target haptic information, and the data unit includes one or more data packets. In addition, the encapsulation module 920 is configured to encapsulate the bit stream, to obtain a media file including the haptic information.

In an embodiment, based on the solution, a syntax structure of the data unit includes a type of the data unit. A different type corresponds to a different binary value. The type of the data unit includes an initialization type, a silent type, a time domain type, and a spatial domain type.

In an embodiment, based on the solution,
in a case that the type of the data unit is the time domain type or the spatial domain type, the syntax structure of the data unit further includes: a first offset timestamp, different timestamps corresponding to different binary values, the first offset timestamp representing a minimum value or a maximum value of timestamps of all data packets included in the data unit, a timestamp of an i^{th} data unit being less than a timestamp of an (i+1)^{th} data unit, and a value of i being a positive integer;
in a case that the type of the data unit is the silent type, the syntax structure of the data unit further includes the first offset timestamp, different timestamps corresponding to different binary values, the first offset timestamp being greater than a maximum value of timestamps of all data packets included in a target data unit, the target data unit being the data unit of the time domain type or the data unit of the spatial domain type preceding the data unit of the silent type;
the syntax structure of the data unit further includes an encoding dependency indicator, different encoding dependency indicators corresponding to different binary values; in a case that a value of the encoding dependency indicator of a current data unit is a first target value, it indicates that the current data unit does not depend on another data unit of the same type during encoding; in a case that the value of the encoding dependency indicator of the current data unit is not the first target value, it indicates that the current data unit depends on the another data unit of the same type during encoding; and if a value of the encoding dependency indicator included in a next data unit of the time domain type or the spatial domain type of the data unit of the initialization type is the first target value, it indicates that the data unit of the initialization type is a decoding initiation unit; and
the syntax structure of the data unit further includes a level indicator and a level identifier, different level indicators corresponding to different binary values, different level identifiers corresponding to different binary values, and a priority of the data unit being determined through a value of the level identifier if the level indicator is a second target value.

In an embodiment, based on the solution, the syntax structure of the data packet includes a type of the data packet, and different types correspond to different binary values.

The type of the data packet includes:
a first type including haptic experience metadata;
a second type including haptic pattern metadata,
a third type including haptic channel metadata,
a fourth type including a knowledge haptic event,
a fifth type including a cyclic check code,
a sixth type including silent information, and
a seventh type including a haptic signal.

In an embodiment, based on the solution, in a case that the type of the data packet is the seventh type, the syntax structure of the data packet further includes a second offset timestamp, and different timestamps correspond to different binary values. The second offset timestamp represents an offset relative to a first timestamp of a data unit where the data packet is located. The second offset timestamp represents a minimum value or a maximum value of timestamps of all haptic events included in the data packet.

In an embodiment, based on the solution, the syntax structure of the data packet further includes a quantity of bytes of a payload, and different quantities of bytes correspond to different binary values.

If the type of the data packet is the first type, the payload of the data packet includes one or more pieces of the following information that are represented through the binary value: a standard version followed by a haptic experience, a string length of a creation date of the haptic experience, the creation date of the haptic experience, a string length of a haptic experience description, the haptic experience description, a time scale of the haptic experience, a quantity of patterns included in the haptic experience, and a quantity of devices corresponding to the haptic experience; and if the type of the data packet is the first type, the payload of the data packet further includes one or more pieces of the following information about a j^{th} device: a device identifier, a string length of a name of the device, a human-readable device name, and an indicator of whether the device corresponds to a body part, a value of j being a positive integer not greater than a quantity of devices corresponding to the haptic experience.

If the type of the data packet is the second type, the payload of the data packet includes one or more pieces of the following information that are represented through the binary value: an identifier of a haptic pattern, a type of the haptic pattern, an indicator of whether semantics exists for a haptic event corresponding to the haptic pattern, an indicator of a specification followed by the semantics of the haptic event, a quantity of devices corresponding to the haptic pattern, a device identifier corresponding to the haptic pattern, and a quantity of haptic channels included in the haptic pattern.

If the type of the data packet is the third type, the payload of the data packet includes one or more pieces of the following information that are represented through the binary value: an identifier of a haptic channel, a haptic pattern identifier corresponding to the haptic channel, a string length of a haptic channel description, the haptic channel description, a gain of the haptic channel, a quantity of devices corresponding to the haptic channel, a device identifier of each device corresponding to the haptic channel, and a quantity of haptic events included in the haptic channel.

If the type of the data packet is the seventh type, the payload of the data packet includes one or more pieces of the following information that are represented through the binary value: an indicator of whether a current data packet depends on another data packet of the same type during encoding, an identifier of a haptic pattern corresponding to a corresponding haptic event in the current data packet, an identifier of a haptic channel corresponding to a haptic event in the current data packet, and a quantity of the haptic events in the data packet; if the type of the data packet is the seventh type, the payload of the data packet further includes one or more pieces of the following information about an m^{th} haptic event: a haptic event identifier, a type of a haptic event, an indicator indicating whether semantics of the haptic event is indicated, semantic information of the haptic event, a knowledge haptic event identifier corresponding to a reference event, a time or space offset of the haptic event, a duration of the haptic event, a maximum signal amplitude value of the haptic event, a signal reference frequency of the haptic event, and a quantity of haptic event components, a value of m being a positive integer not greater than a quantity of the haptic events in the data packet; and if the type of the data packet is the seventh type, the payload of the data packet further includes one or more pieces of the following information about a k^{th} haptic event component: an identifier of a haptic event to which the haptic event component belongs, an indicator of whether the haptic event component includes a time-space domain offset, an indicator of whether the haptic event component includes an amplitude value offset, an indicator of whether the haptic event component includes a frequency offset, a time or space offset of the haptic event component relative to the haptic event, and an amplitude value ratio of the haptic event component relative to the haptic event, a value of k being a positive integer not greater than the quantity of the haptic event components in the haptic event.

If the type of the data packet is the fourth type, the payload of the data packet includes one or more pieces of the following information that are represented through the binary value: an identifier of a haptic pattern corresponding to a knowledge haptic event, and a quantity of knowledge haptic events corresponding to the data packet; if the type of the data packet is the fourth type, the payload of the data packet further includes one or more pieces of the following information about an h^{th} knowledge haptic event: an identifier of the knowledge haptic event, a type of the knowledge haptic event, an indicator of whether to indicate semantics of the knowledge haptic event, semantic information of the knowledge haptic event, a time or space offset of the knowledge haptic event, a duration of the knowledge haptic event, a maximum signal amplitude value of the knowledge haptic event, a signal reference frequency of the knowledge haptic event, and a quantity of haptic event components, a value of h being a positive integer not greater than a quantity of the knowledge haptic events; and if the type of the data packet is the fourth type, the payload of the data packet further includes one or more pieces of the following information about a k^{th} haptic event component: an identifier of a knowledge haptic event to which the haptic event component belongs, an indicator of whether the haptic event component includes a time-space domain offset, an indicator of whether the haptic event component includes an amplitude value offset, an indicator of whether the haptic event component includes a frequency offset, a time or space offset of the haptic event component relative to the knowledge haptic event, and an amplitude value ratio of the haptic event component relative to the knowledge haptic event, a value of k being a positive integer not greater than the quantity of the haptic event components in the knowledge haptic event.

If the type of the data packet is the sixth type, the payload of the data packet includes the following information represented through a binary value: the length of the silent time.

If the type of the data packet is the fifth type, the payload of the data packet includes one or more pieces of the following information represented through the binary value: a type of the cyclic check code, different types of cyclic check codes, and a quantity of data packets protected by the cyclic check code.

The apparatus embodiment and the embodiment of the method for processing haptic information may correspond to each other. For similar descriptions, reference may be made to the method embodiment. To avoid repetition, details are not described herein again. In at least one aspect, the apparatus for processing haptic information shown in FIG. 9 may perform the embodiment of the method for processing haptic information shown in FIG. 7, and the foregoing and other operations and/or functions of various modules in the apparatus for processing haptic information are separately configured for implementing the embodiment of the method for processing haptic information shown in FIG. 7. For brevity, details are not described herein again.

The apparatus in one or more embodiments of this disclosure is described above from the perspective of functional modules with reference to the drawings. The functional modules may be implemented in a form of hardware, or may be implemented by using an instruction in a form of software, or may be implemented by using a combination of hardware and software modules. In at least one aspect, the operations of the method embodiment of the embodiments of this disclosure may be completed by using an integrated logic circuit of hardware in a processor and/or instructions in a form of software. The operations of the method disclosed with reference to the embodiments of this disclosure may be directly performed by a hardware decoding processor, or may be performed and completed by a combination of hardware and software modules in the decoding processor. In some embodiments, the software module may be located in a mature storage medium in the art, such as a random access memory, a flash memory, a read-only memory, a programmable read-only memory, an electrically erasable programmable memory, or a register. The storage medium is located in a memory, and a processor reads information in the memory and completes the operations in the foregoing method embodiment in combination with hardware thereof.

FIG. 10 is a schematic structural diagram of an electronic device 1000 according to an embodiment of this disclosure. The electronic device 1000 in FIG. 10 may be configured to perform the foregoing method for processing haptic information provided in one or more embodiments of FIG. 5, or the electronic device 1000 may be configured to perform the foregoing method for processing haptic information provided in one or more embodiments of FIG. 7.

As shown in FIG. 10, the electronic device 1000 may include:
a memory 1010 (e.g., including a non-transitory computer-readable storage medium) and processing circuitry (e.g., a processor 1020). The memory 1010 is configured to store a computer program 1030 and transmit the computer program 1030 to the processor 1020. In other words, the processor 1020 may invoke the computer program 1030 from the memory 1010 and run the computer program to implement the method for processing haptic information in one or more embodiments of this disclosure.

For example, the processor 1020 may be configured to perform the operations in the foregoing method for processing haptic information according to instructions in the computer program 1030.

In some embodiments of this disclosure, the processor 1020 may include, but is not limited to:
a general-purpose processor, a digital signal processor (DSP), an application specific integrated circuit (ASIC), a field programmable gate array (FPGA), or another programmable logic device, a discrete gate or a transistor logic device, and a discrete hardware component.

In some examples, the memory 1010 includes a non-transitory computer-readable storage medium. In some embodiments of this disclosure, the memory 1010 includes, but is not limited to:
a volatile memory and/or a non-volatile memory. The non-volatile memory may be a read-only memory (ROM), a programmable read-only memory (PROM), an erasable programmable read-only memory (EPROM), an electrically erasable programmable read-only memory (EEPROM), or a flash memory. The volatile memory may be a random access memory (RAM) that is used as an external cache. By way of example but not limitation, many forms of RAMs, such as a static random access memory (SRAM), a dynamic random access memory (DRAM), a synchronous dynamic random access memory (SDRAM), a double data rate synchronous dynamic random access memory (DDR SDRAM), an enhanced synchronous dynamic random access memory (ESDRAM), a synch link dynamic random access memory (SLDRAM), and a direct rambus random access memory (DR RAM) may be used.

In some embodiments of this disclosure, the computer program 1030 may be split into one or more modules. The one or more modules are stored in the memory 1010, and are executed by the processor 1020 to complete the method for processing haptic information in this disclosure. The one or more modules may be a series of computer program instruction sections that can implement specific functions. The instruction sections are configured for describing an execution process of the computer program 1030 in the electronic device.

As shown in FIG. 10, the electronic device 1000 may further include:
a transceiver 1040. The transceiver 1040 may be connected to the processor 1020 or the memory 1010.

The processor 1020 may control the transceiver 1040 to communicate with other devices. In at least one aspect, the transceiver may transmit information or data to the other devices, or may receive information or data transmitted by the other devices. The transceiver 1040 may include a transmitter and a receiver. The transceiver 1040 may further include an antenna. One or more antennas may be provided.

The components of the electronic device 1000 are connected through a bus system. In addition to a data bus, the bus system further includes a power bus, a control bus, and a state signal bus.

According to an aspect of this disclosure, a non-transitory computer-readable storage medium is provided. The non-transitory computer-readable storage medium has a computer program stored therein. The computer program, when executed by a computer, causes the computer to perform the method in the foregoing method embodiment. Alternatively, the embodiments of this disclosure further provide a computer program product including an instruction, the instruction, when executed by a computer, causing the computer to perform the method in the method embodiment.

According to another aspect of this disclosure, a computer program product or a computer program is provided. The computer program product or the computer program includes computer instructions. The computer instructions are stored in a non-transitory computer-readable storage medium. Processing circuitry (e.g., a processor) of a computer device reads the computer instructions from the non-transitory computer-readable storage medium. The processor executes the computer instructions, so that the computer device performs the method in the method embodiments.

In other words, when the embodiments are implemented by using software, all or some of the embodiments may be implemented in a form of a computer program product. The computer program product includes one or more computer instructions. When the computer program instruction is loaded and executed on the computer, all or some processes or functions according to the embodiments of this disclosure are generated. The computer may be a general-purpose computer, a dedicated computer, a computer network, or another programmable apparatus. The computer instruction may be stored in the non-transitory computer-readable storage medium, or may be transmitted from a non-transitory computer-readable storage medium to another non-transitory computer-readable storage medium. For example, the computer instruction may be transmitted from a website, a computer, a server, or a data center to another website, computer, server, or data center in a wired manner (for example, through a coaxial cable, an optical fiber, or a digital subscriber line (DSL)) or a wireless manner (for example, in an infrared, radio, or microwave manner). The non-transitory computer-readable storage medium may be any usable medium that can be accessed by the computer, or may be a data storage device, such as a server or a data center in which one or more usable media are integrated. The usable medium may be a magnetic medium (for example, a floppy disk, a hard disk, or a magnetic tape), an optical medium (for example, a digital video disc (DVD)), a semiconductor medium (for example, a solid state disk (SSD)), or the like.

A person of ordinary skill in the art may be aware that, modules, algorithms, and operations in the examples described with reference to the embodiments disclosed in this specification may be implemented by electronic hardware or a combination of computer software and electronic hardware. Whether these functions are performed by hardware or software depends on specific applications and design constraints of the technical solutions. A person skilled in the art may use different methods to implement the described functions for each specific application, but it is not to be considered that the implementation goes beyond the scope of this disclosure.

In one or more embodiments provided in this disclosure, the disclosed system, apparatus, and method may be implemented in another manner. For example, the described apparatus embodiment is merely an example. For example, division of modules is merely logical function division, and may be another division during actual implementation. For example, a plurality of modules or components may be combined or integrated into another system, or some features may be ignored or not executed. In addition, the displayed or discussed mutual couplings or direct couplings or communication connections may be implemented through some interfaces. The indirect couplings or communication connections between the apparatuses or modules may be implemented in electronic, mechanical, or other forms.

The modules described as separate components may or may not be physically separated, and the components displayed as modules may or may not be physical modules, and may be located in one place or may be distributed over a plurality of network units. Some or all of the modules may be selected according to actual needs to achieve the objectives of the solutions of the embodiments. For example, the functional modules in one or more embodiments of this disclosure may be integrated into one processing module, each of the modules may exist alone physically, or two or more modules may be integrated into one module.

One or more modules, submodules, and/or units of the apparatus can be implemented by processing circuitry, software, or a combination thereof, for example. The term module (and other similar terms such as unit, submodule, etc.) in this disclosure may refer to a software module, a hardware module, or a combination thereof. A software module (for example, computer program) may be developed using a computer programming language and stored in memory or non-transitory computer-readable medium. The software module stored in the memory or medium is executable by a processor to thereby cause the processor to perform the operations of the module. A hardware module may be implemented using processing circuitry, including at least one processor and/or memory. Each hardware module can be implemented using one or more processors (or processors and memory). Likewise, a processor (or processors and memory) can be used to implement one or more hardware modules. Moreover, each module can be part of an overall module that includes the functionalities of the module. Modules can be combined, integrated, separated, and/or duplicated to support various applications. Also, a function being performed at a particular module can be performed at one or more other modules and/or by one or more other devices instead of or in addition to the function performed at the particular module. Further, modules can be implemented across multiple devices and/or other components local or remote to one another. Additionally, modules can be moved from one device and added to another device, and/or can be included in both devices.

The foregoing descriptions are merely non-limiting examples of this disclosure, and are not intended to limit the scope of this disclosure. Any variation or replacement derived by a person skilled in the art within the technical scope disclosed in this disclosure falls within the scope of this disclosure.

What is claimed is:

1. A method for processing haptic information, the method comprising:
obtaining a media file that includes a haptic experience dataset;
obtaining, by processing circuitry from the media file, a bit stream corresponding to the haptic experience dataset, the bit stream including one or more data units, and each one of the one or more data units including one or more data packets and a syntax structure that includes (i) a data unit type indicator indicating a type of the data unit and (ii) a unit-level timestamp indicating an offset time of the data unit from a start time of the haptic experience dataset;
decoding, by the processing circuitry, the bit stream into a piece of text-based interchange format data indicating haptic information of the haptic experience dataset; and
driving one or more haptic devices based on the piece of text-based interchange format data.

2. The method according to claim 1, wherein
for each one of the one or more data units, the data unit type indicator includes a binary value indicating the type of the data unit being one of an initialization type, a silent type, a time domain type, or a spatial domain type.

3. The method according to claim 2, wherein
for a current data unit of the one or more data units, when the data unit type indicator indicates that the type of the current data unit is a time domain type, the offset time indicated by the unit-level timestamp corresponds to a minimum value or a maximum value of timestamps of all of the one or more data packets included in the current data unit, the timestamp of an i^{th} data unit included in the current data unit being less than the timestamp of an (i+1)^{th} data unit included in the current data unit, i being a positive integer.

4. The method according to claim 2, wherein
for a current data unit of the one or more data units, when the data unit type indicator indicates that the type of the current data unit is a silent type, the offset time indicated by the unit-level timestamp is greater than a maximum value of timestamps of all of the one or more data packets included in a target data unit of the one or more data units, the target data unit being a data unit of the time domain type or the spatial domain type preceding the current data unit.

5. The method according to claim 2, wherein
the syntax structure of a current data unit of the one or more data units includes a decoding dependency indicator,
when the decoding dependency indicator is a first target value, the current data unit does not depend on another data unit of a same type during decoding, and
when the decoding dependency indicator is not the first target value, the current data unit depends on at least one other data unit of the same type during decoding.

6. The method according to claim 5, wherein
when the current data unit is of the initialization type and a decoding dependency indicator included in a next data unit of the time domain type or the spatial domain type is the first target value, the current data unit of the initialization type is a decoding initialization unit.

7. The method according to claim 2, wherein
the syntax structure of a current data unit of the one or more data units includes a level indicator and a level identifier, and
when the level indicator is a second target value, a priority of the current data unit is determined based on a value of the level identifier.

8. The method according to claim 1, wherein
each data packet of the one or more data packets of the one or more data units includes a syntax structure that includes a packet type indicator indicating a type of the data packet, and
the type of the data packet includes one of:
a first type corresponding to the data packet including haptic experience dataset metadata;
a second type corresponding to the data packet including haptic pattern metadata;
a third type corresponding to the data packet including haptic channel metadata;
a fourth type corresponding to the data packet including a knowledge haptic event;
a fifth type corresponding to the data packet including a cyclic check code;
a sixth type corresponding to the data packet including silent information; or
a seventh type corresponding to the data packet including a haptic signal.

9. The method according to claim 8, wherein
for a current data packet of the one or more data packets of a current data unit of the one or more data units, when the type of the current data packet is the seventh type, the syntax structure of the current data packet includes a second offset timestamp, and
the second offset timestamp indicates an offset time of the current data packet relative to a time indicated by the unit-level timestamp of the current data unit, the second offset timestamp representing a minimum value or a maximum value of timestamps of all haptic events included in the current data packet.

10. The method according to claim 8, wherein
for a current data packet of the one or more data packets of a current data unit of the one or more data units, the syntax structure of the current data packet includes a quantity of bytes of a payload,
when the type of the current data packet is the first type, the payload of the current data packet includes one or more of: a standard version followed by the haptic experience dataset, a string length of a creation date of the haptic experience dataset, the creation date of the haptic experience dataset, a string length of a haptic experience dataset description, the haptic experience dataset description, a time scale of the haptic experience dataset, a quantity of patterns included in the haptic experience dataset, or a quantity of devices corresponding to the haptic experience dataset, and
when the type of the current data packet is the first type, the payload of the current data packet further includes one or more of: a device identifier of a j^{th} device, a string length of a name of the j^{th} device, a human-readable device name of the j^{th} device, or an indicator of whether the j^{th} device corresponds to a body part, j being a positive integer not greater than a quantity of devices corresponding to the haptic experience dataset.

11. The method according to claim 8, wherein
for a current data packet of the one or more data packets of a current data unit of the one or more data units, the syntax structure of the current data packet includes a quantity of bytes of a payload of the current data packet, and
when the type of the current data packet is the second type, the payload of the data packet includes one or more of: an identifier of a haptic pattern, a type of the haptic pattern, an indicator of whether semantics exists for a haptic event corresponding to the haptic pattern, an indicator of a standard followed by the semantics of the haptic event, a quantity of devices corresponding to the haptic pattern, a device identifier corresponding to the haptic pattern, or a quantity of haptic channels included in the haptic pattern.

12. The method according to claim 8, wherein
for a current data packet of the one or more data packets of a current data unit of the one or more data units, the syntax structure of the current data packet includes a quantity of bytes of a payload of the current data packet, and
when the type of the current data packet is the third type, the payload of the data packet includes one or more of: an identifier of a haptic channel, a haptic pattern identifier corresponding to the haptic channel, a string length of a haptic channel description, the haptic channel description, a gain of the haptic channel, a quantity of devices corresponding to the haptic channel, a device identifier of each device corresponding to the haptic channel, or a quantity of haptic events included in the haptic channel.

13. The method according to claim 8, wherein
for a current data packet of the one or more data packets of a current data unit of the one or more data units, the syntax structure of the current data packet includes a quantity of bytes of a payload of the current data packet,
when the type of the current data packet is the seventh type, the payload of the current data packet includes one or more of: an indicator of whether the current data packet depends on another data packet of a same type during decoding, an identifier of a haptic pattern corresponding to a haptic event in the current data packet, an identifier of a haptic channel corresponding to the haptic event in the current data packet, or a quantity of haptic events in the current data packet,
when the type of the current data packet is the seventh type, the payload of the data packet further includes one or more oft: a haptic event identifier of an m^{th} haptic event, a type of the m^{th} haptic event, an indicator indicating whether semantics of the m^{th} haptic event is indicated, semantic information of the m^{th} haptic event, a knowledge haptic event identifier corresponding to a reference event, a time or space offset of the m^{th} haptic event, a duration of the m^{th} haptic event, a maximum signal amplitude value of the m^{th} haptic event, a signal reference frequency of the m^{th} haptic event, or a quantity of haptic event components, m being a positive integer not greater than a quantity of haptic events in the current data packet, and
when the type of the current data packet is the seventh type, the payload of the data packet further includes one or more of: an identifier of a current haptic event to which a k^{th} haptic event component belongs, an indicator of whether the k^{th} haptic event component includes a time-space domain offset, an indicator of whether the k^{th} haptic event component includes an amplitude value offset, an indicator of whether the k^{th} haptic event component includes a frequency offset, a time or space offset of the k^{th} haptic event component relative to the current haptic event, or an amplitude value ratio of the k^{th} haptic event component relative to the current haptic event, k being a positive integer not greater than the quantity of the haptic event components in the current haptic event.

14. The method according to claim 8, wherein
for a current data packet of the one or more data packets of a current data unit of the one or more data units, the syntax structure of the current data packet includes a quantity of bytes of a payload,
when the type of the current data packet is the fourth type, the payload of the current data packet includes one or more of: an identifier of a haptic pattern corresponding to a preset haptic event, or a quantity of preset haptic events corresponding to the current data packet,
when the type of the current data packet is the fourth type, the payload of the current data packet further includes one or more of: an identifier of an h^{th} preset haptic event, a type of the h^{th} preset haptic event, an indicator of whether to indicate semantics of the h^{th} preset haptic event, semantic information of the h^{th} preset haptic event, a time or space offset of the h^{th} preset haptic event, a duration of the h^{th} preset haptic event, a maximum signal amplitude value of the h^{th} preset haptic event, a signal reference frequency of the h^{th} preset haptic event, or a quantity of haptic event components of the h^{th} preset haptic event, h being a positive integer not greater than a quantity of preset haptic events in the current data packet, and
when the type of the current data packet is the fourth type, the payload of the data packet further includes one or more of: an identifier of a current preset haptic event to which a k^{th} haptic event component belongs, an indicator of whether the k^{th} haptic event component includes a time-space domain offset, an indicator of whether the k^{th} haptic event component includes an amplitude value offset, an indicator of whether the k^{th} haptic event component includes a frequency offset, a time or space offset of the k^{th} haptic event component relative to the current preset haptic event, or an amplitude value ratio of the k^{th} haptic event component relative to the current preset haptic event, k being a positive integer not greater than a quantity of haptic event components in the current preset haptic event.

15. The method according to claim 8, wherein
for a current data packet of the one or more data packets of a current data unit of the one or more data units, the syntax structure of the current data packet includes a quantity of bytes of a payload, and
when the type of the current data packet is the sixth type, the payload of the current data packet includes a length of a silent time.

16. The method according to claim 8, wherein
for a current data packet of the one or more data packets of a current data unit of the one or more data units, the syntax structure of the current data packet includes a quantity of bytes of a payload, and
when the type of the current data packet is the fifth type, the payload of the current data packet includes one or more of: a type of the cyclic check code, a bit length of the cyclic check code, or a quantity of data packets protected by the cyclic check code.

17. A method for processing haptic information, the method comprising:
obtaining a piece of text-based interchange format data indicating haptic information;
encoding, by processing circuitry, the piece of text-based interchange format data into a binary bit stream corresponding to a haptic experience dataset incorporating the haptic information, the bit stream including one or more data units, and each one of the one or more data units including one or more data packets and a syntax structure that includes (i) a data unit type indicator indicating a type of the data unit and (ii) a unit-level timestamp indicating an offset time of the data unit from a start time of the haptic experience dataset;
obtaining, by the processing circuitry, a media file encapsulating the haptic experience dataset; and
transmitting the media file to a processing device that is configured to decode the media file into the piece of text-based interchange format data and drive one or more haptic devices based on the piece of text-based interchange format data.

18. The method according to claim 17, wherein
for each one of the one or more data units, the data unit type indicator includes a binary value indicating the type of the data unit being one of an initialization type, a silent type, a time domain type, or a spatial domain type.

19. The method according to claim 17, wherein
each data packet of the one or more data packets of the one or more data units includes a syntax structure that includes a packet type indicator indicating a type of the data packet, and
the type of the data packet includes one of:
a first type corresponding to the data packet including haptic experience dataset metadata;
a second type corresponding to the data packet including haptic pattern metadata;
a third type corresponding to the data packet including haptic channel metadata;
a fourth type corresponding to the data packet including a knowledge haptic event;
a fifth type corresponding to the data packet including a cyclic check code;
a sixth type corresponding to the data packet including silent information; or
a seventh type corresponding to the data packet including a haptic signal.

20. A haptic information processing device, comprising:
processing circuitry configured to:
obtain a media file that includes a haptic experience dataset;
obtain, from the media file, a bit stream corresponding to the haptic experience dataset, the bit stream including one or more data units, and each one of the one or more data units including one or more data packets and a syntax structure that includes (i) a data unit type indicator indicating a type of the data unit and (ii) a unit-level timestamp indicating an offset time of the data unit from a start time of the haptic experience dataset;
decode the bit stream into a piece of text-based interchange format data indicating haptic information of the haptic experience dataset; and
drive one or more haptic devices based on the piece of text-based interchange format data.
